(19) United States
(12) Patent Application Publication
(10) Pub. No.: US 2023/0223479 A1
(43) Pub. Date: Jul. 13, 2023

(54) THIN FILM TRANSISTOR AND MANUFACTURING METHOD FOR THE SAME

(71) Applicant: ADRC. CO. KR, Seoul (KR)

(72) Inventors: Jin JANG, Seoul (KR); Hae Su Hong, Seoul (KR)

(21) Appl. No.: 17/720,426

(22) Filed: Apr. 14, 2022

(30) Foreign Application Priority Data
Jan. 7, 2022 (KR) 10-2022-0003009

(51) Int. Cl. H01L 29/786; H01L 29/66

(52) U.S. Cl. CPC H01L 29/7869; H01L 29/78618; H01L 29/66742

(57) ABSTRACT

A thin film transistor according to an embodiment includes: a gate electrode positioned on a substrate; a semiconductor layer overlapping the gate electrode via a gate insulating layer interposed therebetween; and a source electrode and a drain electrode in contact with the semiconductor layer, wherein the semiconductor layer includes a crystallized oxide semiconductor, and the crystallized oxide semiconductor includes a crystal of which an X-ray diffraction (XRD) main peak Miller index (hkI) value is 009.

### CROSS-REFERENCE TO RELATED APPLICATION

This application claims priority to and the benefit of Korean Patent Application No. 10-2022-0003009 filed in the Korean Intellectual Property Office on Jan. 7, 2022, the entire contents of which are incorporated herein by reference.

### BACKGROUND OF THE INVENTION

### (a) Field of the Invention

The present disclosure relates to a transistor and a manufacturing method thereof.

### (b) Description of the Related Art

A thin film transistor constitutes a switching device with three terminals: a gate electrode to which a control signal is applied, a source electrode to which a data voltage is applied, and a drain electrode to output the data voltage. In addition, such a thin film transistor includes an active layer overlapping the gate electrode as a channel layer, and the active layer includes a semiconductor.

On the other hand, with development of a display technology including the thin film transistor, development of the thin film transistor capable of high-speed driving is urgently needed. For this, a technology using an oxide semiconductor with high electron mobility as an active layer has been developed, but a thin film transistor with improved performance is required to be used for high-speed operation.

In addition, since the manufacturing cost increases as the manufacturing process of the thin film transistor with improved performance becomes more complex, it is necessary to provide the thin film transistor and the manufacturing method that is capable of maintaining high performance while lowering the manufacturing cost by simplifying the manufacturing process.

The above information disclosed in this Background section is only for enhancement of understanding of the background of the invention, and therefore it may contain information that does not form the prior art that is already known in this country to a person of ordinary skill in the art.

### SUMMARY OF THE INVENTION

Embodiments are to provide a thin film transistor capable of lowering the manufacturing cost and maintaining high performance, and a manufacturing method thereof.

However, the problems to be solved by embodiments are not limited to the above-described problem and may be variously extended in a range of technical ideas included in embodiments.

A thin film transistor according to an embodiment includes: a gate electrode positioned on a substrate; a semiconductor layer overlapping the gate electrode via a gate insulating layer interposed therebetween; and a source electrode and a drain electrode in contact with the semiconductor layer, wherein the semiconductor layer includes a crystallized oxide semiconductor, and the crystallized oxide semiconductor includes a crystal of which an X-ray diffraction (XRD) main peak Miller index (hkI) value is 009.

The crystal of the crystallized oxide semiconductor may include CAAC (C Axis Aligned Crystal).

The axes of the CAAC may be arranged in line along the thickness direction of the semiconductor layer,

The semiconductor layer may include indium.

The semiconductor layer may include at least one among IGZO (Indium-Gallium-Zinc-Oxide), IZTO (Indium-Zinc-Tin-Oxide), IGZTO (Indium-Gallium-Zinc-Tin-Oxide), and IGO (Indium-Gallium-Oxide).

At least portion of the semiconductor layer may be treated by fluorine plasma.

A thin film transistor according to an embodiment includes: a gate electrode positioned on a substrate; a semiconductor layer overlapping the gate electrode via a gate insulating layer interposed therebetween; and a source electrode and a drain electrode in contact with the semiconductor layer, wherein the semiconductor layer includes a crystallized oxide semiconductor, the crystallized oxide semiconductor includes a CAAC (C Axis Aligned Crystal), and the axes of the CAAC are arranged in line along the thickness direction of the semiconductor layer.

A manufacturing method of a thin film transistor according to an embodiment includes: forming a gate electrode on a substrate; forming an semiconductor layer overlapping the gate electrode via a gate insulating layer interposed therebetween on the substrate; and forming a source electrode and a drain electrode in contact with the semiconductor layer, wherein the forming of the semiconductor layer includes spray-coating a solution including a volatile solvent, a metal precursor, and a stabilizer on the substrate.

The spray coating may include preparing the solution by: mixing the metal precursor and the stabilizer in the volatile solvent; spraying the solution with a carrier gas on the substrate; and evaporating the volatile solvent of the solution.

The spray coating may be performed under a temperature of about 300° C. or higher.

The stabilizer may include ammonium acetate (AA).

The forming of the semiconductor layer may repeat the spray coating several times.

The manufacturing method may further include performing a fluorine plasma treatment on at least portion of the semiconductor layer.

The fluorine plasma treatment may be performed on the semiconductor layer by using the gate electrode as a mask to perform the fluorine plasma treatment.

According to the thin film transistor and the manufacturing method thereof according to the embodiment, it is possible to lower the manufacturing cost and maintain high performance.

It is apparent that the effect of the present invention is not limited to the above-described effect, but may be variously extended within a range without departing from the spirit and scope of the present invention.

### BRIEF DESCRIPTION OF THE DRAWINGS

FIG. 1 is a cross-sectional view of a thin film transistor according to an embodiment.

FIG. 2 is a cross-sectional view of a thin film transistor according to another embodiment.

FIG. 3A to FIG. 3C are cross-sectional views showing a manufacturing method of a thin film transistor according to an embodiment.

FIG. 4A and FIG. 4B are cross-sectional views showing a manufacturing method of a thin film transistor according to another embodiment.

FIG. 5 to FIG. 8 are transmission electron micrographs showing a result of an experimental example.

FIG. 9A and FIG. 9B are transmission electron micrographs showing a result of another experimental example.

FIG. 10A to FIG. 100 are graphs showing a result of another experimental example.

FIG. 11A to FIG. 11C, FIG. 12A to FIG. 12C, FIG. 13A and FIG. 13B, FIG. 14A and FIG. 14B, FIG. 15A to FIG. 15C, FIG. 16A to FIG. 16C, FIG. 17A to FIG. 17C, and FIG. 18A to FIG. 18C are views showing an image showing a result of another experimental example.

FIG. 19A and FIG. 19B are graphs showing a result of another experimental example.

FIG. 20A to FIG. 20C and FIG. 21A to FIG. 21C are images showing a result of another experimental example.

FIG. 22A to FIG. 22C are graphs showing a result of another experimental example.

FIG. 23A to FIG. 23C, FIG. 24A to FIG. 24C, and FIG. 25A to FIG. 25E are graphs showing a result of another experimental example.

FIG. 26A to FIG. 26C are graphs showing a result of another experimental example.

FIG. 27A to FIG. 27D are graphs showing a result of another experimental example.

FIG. 28A and FIG. 28B, FIG. 29A and FIG. 29B, and FIG. 30A and FIG. 30B are graphs showing a result of another experimental example.

### DETAILED DESCRIPTION OF THE EMBODIMENTS

The present invention will be described more fully hereinafter with reference to the accompanying drawings, in which embodiments of the invention are shown. As those skilled in the art would realize, the described embodiments may be modified in various different ways, all without departing from the spirit or scope of the present invention.

Descriptions of parts not related to the present invention are omitted, and like reference numerals designate like elements throughout the specification.

In addition, the attached drawings are only for easy understanding of embodiments disclosed in the present specification, and technical ideas disclosed in the present specification are not limited by the attached drawings, and it should be understood to include all modifications, equivalents, or substitutes included in the ideas and technical ranges of the present invention.

Further, since sizes and thicknesses of constituent members shown in the accompanying drawings are arbitrarily given for better understanding and ease of description, the present invention is not limited to the illustrated sizes and thicknesses. In the drawings, the thickness of layers, films, panels, regions, etc., are exaggerated for clarity. In the drawings, for better understanding and ease of description, the thicknesses of some layers and areas are exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, the word “on” or “above” means positioned on or below the object portion and does not necessarily mean positioned on the upper side of the object portion based on a gravitational direction.

In addition, unless explicitly described to the contrary, the word “comprise”, and variations such as “comprises” or “comprising”, will be understood to imply the inclusion of stated elements but not the exclusion of any other elements.

Throughout the specification, the phrase “on a plane” means viewing the object portion from the top, and the phrase “on a cross-section” means viewing a cross-section of which the object portion is vertically cut from the side.

In addition, in the specification, when referring to “connected to”, this does not only mean that two or more constituent elements are directly connected to, but also that two or more constituent elements are electrically connected through other constituent elements as well as being indirectly connected to and being physically connected to, or it may mean that they are referred to by different names according to a position or function, but are integrated.

Hereinafter, various embodiments and variations will be described in detail with reference to the drawings.

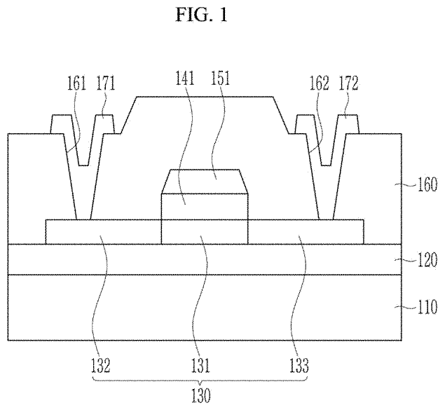

A thin film transistor according to an embodiment is described with reference to FIG. 1. FIG. 1 is a cross-sectional view of a thin film transistor according to an embodiment.

Referring to FIG. 1, a buffer layer 120 is positioned on a substrate 110. The buffer layer 120 may have a single-layered or multi-layered structure. In FIG. 1, the buffer layer 120 is illustrated as a single layer, but may be multi-layered according to an embodiment. The buffer layer 120 may include an organic insulating material or an inorganic insulating material. For example, the buffer layer 120 may include at least one of a silicon nitride (SiNx), a silicon oxide (SiOx), and a silicon oxynitride (SiOxNy).

A semiconductor layer 130 including a first region 131, a second region 132, and a third region 133 is positioned on the buffer layer 120.

The semiconductor layer 130 may include an oxide semiconductor. The oxide semiconductor may include at least one among a primary metal oxide such as indium (In) oxide, tin (Sn) oxide, or zinc (Zn) oxide, a binary metal oxide such as In—Zn-based oxides, Sn—Zn-based oxides, Al—Zn-based oxides, Zn—Mg-based oxides, Sn—Mg-based oxides, In—Mg-based oxides, or In—Ga-based oxides, a ternary metal oxide such as In—Ga—Zn-based oxides, In—Al—Zn-based oxides, In—Sn—Zn-based oxides, Sn—Ga—Zn-based oxides, Al—Ga—Zn-based oxides, Sn—Al—Zn-based oxides, In—Hf—Zn-based oxides, In—La—Zn-based oxides, In—Ce—Zn-based oxides, In—Pr—Zn-based oxides, In—Nd—Zn-based oxides, In—Sm—Zn-based oxides, In—Eu—Zn-based oxides, In—Gd—Zn-based oxides, In—Tb—Zn-based oxides, In—Dy—Zn-based oxides, In—Ho—Zn-based oxides, In—Er—Zn-based oxides, In—Tm—Zn-based oxides, In—Yb—Zn-based oxides, or In—Lu—Zn-based oxides, and a quaternary metal oxide such as In—Sn—Ga—Zn-based oxides, In—Hf—Ga—Zn-based oxides, In—Al—Ga—Zn-based oxides, In—Sn—Al—Zn-based oxides, In—Sn—Hf—Zn-based oxides, or In—Hf—Al—Zn-based oxides. For example, the oxide semiconductor may include Indium-Gallium-Zinc-Oxide (IGZO) among the In—Ga—Zn-based oxide.

The semiconductor layer 130 may include at least one of IGZO (Indium-Gallium-Zinc-Oxide), IZTO (Indium-Zinc-Tin-Oxide), IGZTO (Indium-Gallium-Zinc-Tin-Oxide), and IGO (Indium-Gallium Oxide).

The semiconductor layer 130 may be formed by a spray method, a spray solution may include a stabilizer, and the stabilizer may include ammonium acetate (CH3CO2NH4) (AA).

The first region 131 of the semiconductor layer 130 may be a channel region, and the second region 132 and the third region 133 of the semiconductor layer 130 may be a source region and a drain region.

The semiconductor layer 130 may be formed by a spray coating method, and may be crystallized without a separate annealing process. The crystal of the semiconductor layer 130 may include a C Axis Aligned Crystal (CAAC) with an XRD (X-ray diffraction) main peak Miller index (hkI) value corresponds to 009, in the semiconductor layer 130, from the bottom surface adjacent to the buffer layer 120 to the top surface adjacent to the gate insulating layer 141 to be described later, the axis of the CAAC of which the XRD main peak Miller index (hkI) value corresponding to 009 is sorted and aligned along the thickness direction.

At least a portion of the semiconductor layer 130 may be treated with fluorine plasma. By doping at least portion of the semiconductor layer 130 by treating with fluorine plasma, the efficiency of a channel of the thin film transistor may be increased by reducing a resistance and increasing a carrier concentration.

The gate insulating layer 141 is positioned on the first region 131 of the semiconductor layer 130. The gate insulating layer 141 may include an organic insulating material or an inorganic insulating material, for example, the gate insulating layer 141 may include at least among a silicon nitride, a silicon oxide, a silicon oxynitride, and tetraethyl orthosilicate (TEOS).

A gate electrode 151 is positioned on the gate insulating layer 141. The gate electrode 151 is disposed to overlap the first region 131 of the semiconductor layer 130, and the gate insulating layer 141 is positioned between the first region 131 of the semiconductor layer 130 and the gate electrode 151.

The gate electrode 151 may be a multilayer in which a metal film including any one of copper (Cu), a copper alloy, aluminum (Al), an aluminum alloy, molybdenum (Mo), and a molybdenum alloy is stacked.

A protective layer 160 is positioned on the semiconductor layer 130, the gate insulating layer 141, and the gate electrode 151. The protection layer 160 may include at least one of a silicon nitride, a silicon oxide, a silicon oxynitride, and tetraethyl orthosilicate (TEOS), and may be made of organic materials such as a polyacrylate resin, a polyimide resin, or laminated films of organic materials and inorganic materials.

The protection layer 160 has a first contact hole 161 overlapping the second region 132 of the semiconductor layer 130 and a second contact hole 172 overlapping the third region 133 of the semiconductor layer 130.

A source electrode 171 and a drain electrode 172 are positioned on the protection layer 160. The source electrode 171 is connected to the second region 132, which is the source region of the semiconductor layer 130, by the first contact hole 161 of the protection layer 160, and the drain electrode 172 is connected to the third region 133, which is the drain region of the semiconductor layer 130, by the second contact hole 162 of the protection layer 160.

The source electrode 171 and the drain electrode 172 may include an aluminum-based metal, a silver-based metal, or a copper-based metal having low resistivity, for example, may have a triple-layer structure of a lower film including a refractory metal or alloys thereof, such as titanium, molybdenum, chromium, and tantalum; an interlayer film including aluminum-based metal, silver-based metal, and copper-based metal with low resistivity; and an upper layer including a refractory metal such as titanium, molybdenum, chromium, and tantalum.

The gate electrode 151, source electrode 171 and drain electrode 172 described above form a thin film transistor (TFT) together with the semiconductor layer 130, and the channel of the thin film transistor is formed in the first region 131 between the second region that is the source region of the semiconductors 131, 132, and 133 and the third region 133, which is the drain region.

According to the thin film transistor according to the present embodiment, the semiconductor layer 130 may include the oxide semiconductor, the semiconductor layer 130 may be formed by the spray coating method, in the semiconductor layer 130, from the bottom surface adjacent to the buffer layer 120 to the top surface adjacent to the gate insulating layer 141 to be described later, the axis of the CAAC of which the XRD main peak Miller index (hkI) value corresponding to 009 may be sorted and aligned along the thickness direction.

When the oxide semiconductor layer constituting the semiconductor layer of the thin film transistor is crystallized, the performance of the thin film transistor may be higher than that of the thin film transistor including a non-crystallized oxide semiconductor layer. In general, to crystallize the oxide semiconductor layer, the oxide semiconductor layer may be stacked and annealing may be performed at a high temperature to be crystallized. However, when the oxide semiconductor layer is crystallized by the annealing at a high temperature, the crystallization of the surface to which the energy of a high temperature is applied may be large and the crystallization may decrease toward the opposite surface, and the crystallization may be made non-uniform according to the energy distribution. In addition, by including an annealing process for the separate crystallization, the manufacturing cost may be high.

However, as described above, as the semiconductor layer of the thin film transistor according to the present embodiment is formed by the spray coating method, it may have the CAAC crystal having the axis that is sorted and aligned from the bottom surface to the top surface without the separate annealing process, and since the manufacturing process is not complicated, the performance of the transistor may be improved without increasing the manufacturing cost.

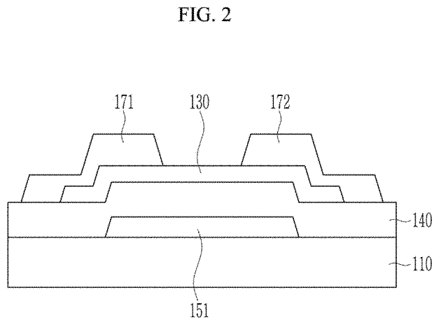

Next, the thin film transistor according to another embodiment is described with reference to FIG. 2. FIG. 2 is a cross-sectional view of a thin film transistor according to another embodiment.

Referring to FIG. 2, a gate electrode 151 may be positioned on a substrate 110, and a gate insulating layer 141 may be positioned on the gate electrode 151.

The gate electrode 151 may be a multilayer in which a metal film including any one of copper (Cu), a copper alloy, aluminum (Al), an aluminum alloy, molybdenum (Mo), and a molybdenum alloy is stacked.

The gate insulating layer 141 may include an organic insulating material or an inorganic insulating material, for example, the gate insulating layer 141 may include at least one among a silicon nitride, a silicon oxide, a silicon oxynitride, and tetraethyl orthosilicate (TEOS).

A semiconductor layer 130 including a first region 131, a second region 132, and a third region 133 is positioned on the gate insulating layer 141.

The semiconductor layer 130 may include an oxide semiconductor. The oxide semiconductor may include at least one among a primary metal oxide such as indium (In) oxide, tin (Sn) oxide, or zinc (Zn) oxide, a binary metal oxide such as In—Zn-based oxides, Sn—Zn-based oxides, Al—Zn-based oxides, Zn—Mg-based oxides, Sn—Mg-based oxides, In—Mg-based oxides, or In—Ga-based oxides, a ternary metal oxide such as In—Ga—Zn-based oxides, In—Al—Zn-based oxides, In—Sn—Zn-based oxides, Sn—Ga—Zn-based oxides, Al—Ga—Zn-based oxides, Sn—Al—Zn-based oxides, In—Hf—Zn-based oxides, In—La—Zn-based oxides, In—Ce—Zn-based oxides, In—Pr—Zn-based oxides, In—Nd—Zn-based oxides, In—Sm—Zn-based oxides, In—Eu—Zn-based oxides, In—Gd—Zn-based oxides, In—Tb—Zn-based oxides, In—Dy—Zn-based oxides, In—Ho—Zn-based oxides, In—Er—Zn-based oxides, In—Tm—Zn-based oxides, In—Yb—Zn-based oxides, or In—Lu—Zn-based oxides, and a quaternary metal oxide such as In—Sn—Ga—Zn-based oxides, In—Hf—Ga—Zn-based oxides, In—Al—Ga—Zn-based oxides, In—Sn—Al—Zn-based oxides, In—Sn—Hf—Zn-based oxides, or In—Hf—Al—Zn-based oxides.

The semiconductor layer 130 may include at least one of an IGZO (Indium-Gallium-Zinc-Oxide), an IZTO (Indium-Zinc-Tin-Oxide), an IGZTO (Indium-Gallium-Zinc-Tin-Oxide), and an IGO (Indium-Gallium-Oxide).

The semiconductor layer 130 may be formed by a spray method, a spray solution may include a stabilizer, and the stabilizer may include ammonium acetate (CH3CO2NH4) (AA).

The first region 131 of the semiconductor layer 130 may be a channel region, and the second region 132 and the third region 133 of the semiconductor layer 130 may be a source region and a drain region.

The semiconductor layer 130 may be formed by a spray coating method, and may be crystallized without a separate annealing process. The crystal of the semiconductor layer 130 may include a C Axis Aligned Crystal (CAAC) having an X-ray diffraction (XRD) main peak Miller index (hkI) value of 009, and in the semiconductor layer 130, from the bottom surface adjacent to the gate insulating layer 141 to the top surface adjacent to the source electrode 171 and drain electrode 172 to be described later, the CAAC axes with the XRD main peak Miller index (hkI) value of 009 may be sorted and aligned.

At least a portion of the semiconductor layer 130 may be treated with fluorine plasma. By doping at least portion of the semiconductor layer 130 by treating with fluorine plasma, the efficiency of a channel of the thin film transistor may be increased by reducing the resistance and increasing the carrier concentration.

The source electrode 171 is positioned on the second region 132 that is the source region of the semiconductor layer 130, and the drain electrode 172 is positioned on the third region 133 that is the drain region of the semiconductor layer 130.

The source electrode 171 and the drain electrode 172 may include: an aluminum-based metal, a silver-based metal, or a copper-based metal having low resistivity, for example, may have a triple-layer structure of a lower film including a refractory metal or alloys thereof, such as titanium, molybdenum, chromium, and tantalum; an interlayer film including an aluminum-based metal, a silver-based metal, and a copper-based metal with low resistivity; and an upper layer including a refractory metal such as titanium, molybdenum, chromium, and tantalum.

The gate electrode 151, the source electrode 171, and the drain electrode 172 described above form the thin film transistor together with the semiconductor layer 130, and the channel of the thin film transistor is formed in the first region 131 between the second region 132, which is the source region, and the third region 133, which is the drain region, of the semiconductors 131, 132, and 133.

According to the thin film transistor according to the present embodiment, the semiconductor layer 130 may include the oxide semiconductor, the semiconductor layer 130 may be formed by the spray coating method, and in the semiconductor layer 130, from the bottom surface adjacent to the buffer layer 120 to the top surface adjacent to the gate insulating layer 141 to be described later, the axis of the CAAC of which the XRD main peak Miller index (hkI) value corresponding to 009 may be sorted and aligned.

As described above, as the semiconductor layer of the thin film transistor according to the present embodiment is formed by the spray coating method, it may have the CAAC crystal having the axis that is sorted and aligned from the bottom surface to the top surface without the separate annealing process, and since the manufacturing process is not complicated, the performance of the transistor may be improved without increasing the manufacturing cost.

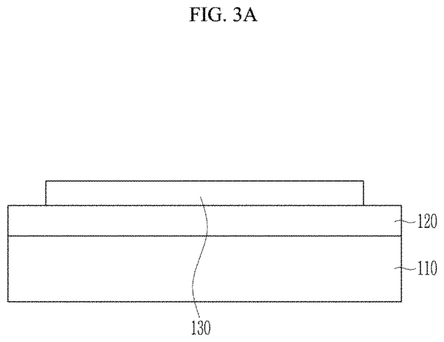

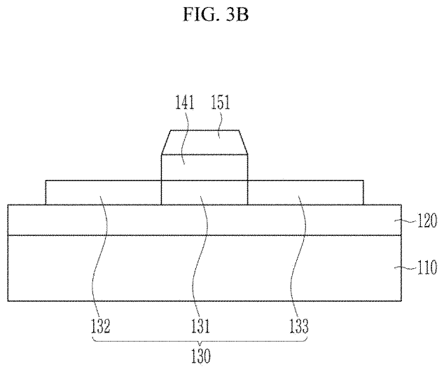

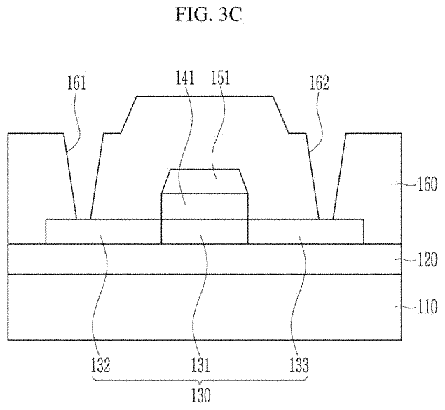

A manufacturing method of the thin film transistor according to an embodiment is described with reference to FIG. 3A to FIG. 3C along with FIG. 1. FIG. 3A to FIG. 3C are cross-sectional views showing a manufacturing method of a thin film transistor according to an embodiment.

As shown in FIG. 3A, a buffer layer 120 is stacked on a substrate 110, and a semiconductor layer 130 is formed on the buffer layer 120.

The semiconductor layer 130 may be stacked by the spray coating method. The semiconductor layer 130 be formed by repeating processes of mixing a metal precursor and a stabilizer included in the oxide semiconductor with a volatile solvent under a temperature of about 300° C. or higher and evaporating the volatile solvent after spraying the solution with a carrier gas such as nitrogen to form a thin semiconductor thin film several times.

The semiconductor layer 130 may include at least one among IGZO (Indium-Gallium-Zinc-Oxide), IZTO(Indium-Zinc-Tin-Oxide), IGZTO(Indium-Gallium-Zinc-Tin-Oxide), IGO (Indium-Gallium-Oxide), for example, an indium (In) precursor may include Indium(III) chloride (InCl₃), a gallium (Ga) precursor may include Gallium(III) nitrate hydrate (Ga (NO₃)₃·xH₂O), a zinc (Zn) precursor may include Zinc acetate dehydrate (Zn (CH₃COO)₂·2H₂O), and a tin (Sn) precursor may include Tin(II) chloride dihydrate (SnCl₂·2H₂O).

The stabilizer may include Ammonium acetate (CH₃CO₂NH₄)) (AA), and the solvent may include 2-Methoxyethanol (CH₃OCH₂CH₂OH).

As the spray coating process is repeated, the thickness of the semiconductor layer 130 may become thicker, and the crystal size of the semiconductor layer 130 may increase.

The semiconductor layer 130 may have a C Axis Aligned Crystal (CAAC) crystal having an X-ray diffraction (XRD) main peak Miller index (hkI) value of 009.

If the spray coating process is repeated to stack the semiconductor layer 130, the crystals may be sorted and aligned from the bottom to the top along the thickness direction of the semiconductor layer 130 as the thin semiconductor layer is stacked several times.

When the spray coating process is performed, a crystal nucleus is formed in the semiconductor layer at the beginning of the process, as an additional semiconductor layer is stacked on the crystal nucleus by the spray coating process, the crystal grows around the crystal nucleus and is crystallized, and as these processes are repeated, the central axes of the crystals may be aligned from the bottom to the top of the semiconductor layer 130.

The semiconductor layer 130 including the crystallized oxide semiconductor layer is formed by stacking the semiconductor layer 130 by the spray coating method, and as shown in FIG. 3B, the gate insulating layer 141 and the gate electrode 151 may be formed to overlap the first region of the semiconductor layer 130.

After forming the gate insulating layer 141 and the gate electrode 151, the semiconductor layer 130 may be treated with fluorine plasma by using the gate insulating layer 141 and the gate electrode 151 as a mask, and the second region 132 and the third region 133 of the semiconductor layer 130 may be doped with impurities of fluorine through the fluorine plasma treatment.

As shown in FIG. 3C, a protection layer 160 is stacked and patterned to form a first contact hole 161 and a second contact hole 162 of the protection layer 160, and then a source electrode 171 connected to the second region 132 of the semiconductor layer 130 through the first contact hole 161 and a drain electrode 172 connected to the third region 133 of the semiconductor layer 130 through the second contact hole 162 are formed, and as shown in FIG. 1, a thin film transistor may be formed.

According to the manufacturing method of the thin film transistor according to the present embodiment, by repeating the processes of spraying the solution in which the precursor of the material included in the oxide semiconductors and the stabilizer are mixed with the volatile solvent with the carrier gas such as nitrogen and then evaporating the volatile solvent under the temperature of about 300° C. or higher to form the thin semiconductor thin film, the crystallized oxide semiconductor layer 130 including the crystal of the C Axis Aligned Crystal (CAAC) of which the crystal axis is aligned with the thickness direction and the XRD (X-ray diffraction) main peak Miller index (hkI) value corresponds to 009 may be formed.

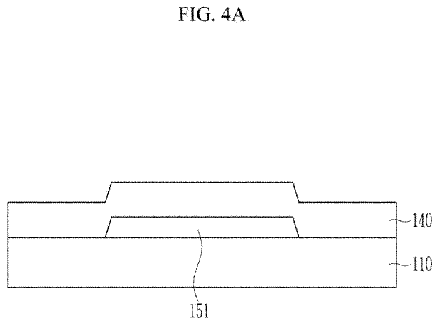

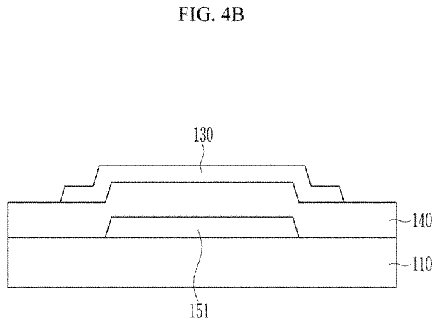

The manufacturing method of the thin film transistor according to another embodiment is described with reference to FIG. 4A and FIG. 4B along with FIG. 2. FIG. 4A and FIG. 4B are cross-sectional views showing a manufacturing method of a thin film transistor according to another embodiment.

As shown in FIG. 4A, a gate electrode 151 is formed on a substrate 110, and a gate insulating layer 141 is formed on the gate electrode 151.

As shown in FIG. 4B, on the gate insulating layer 141, a semiconductor layer 130 is formed by the spray coating method under a temperature of about 300° C. or higher.

The semiconductor layer 130 may be formed by repeating the processes of spraying the solution in which the precursor of the material included in the oxide semiconductor and the stabilizer are mixed with the volatile solvent with the carrier gas such as nitrogen and evaporating the volatile solvent to form the thin semiconductor thin film several times.

The indium (In) precursor may include Indium(III) chloride (InCl₃), the gallium(Ga) precursor may include Gallium(III) nitrate hydrate (Ga N(O₃)₃·xH₂O), the zinc (Zn) precursor may include Zinc acetate dehydrate (Zn (CH₃COO)₂·2H₂O), and the tin (Sn) precursor may include Tin(II) chloride dihydrate (SnCl₂·2H₂O).

The stabilizer may include Ammonium acetate (CH₃CO₂NH₄)) (AA), and the solvent may include 2-Methoxyethanol (CH₃OCH₂CH₂OH).

As the spray coating process is repeated, the thickness of the semiconductor layer 130 may become thicker, and the crystal size of the semiconductor layer 130 may increase.

The semiconductor layer 130 may have the C Axis Aligned Crystal (CAAC) crystal having an X-ray diffraction (XRD) main peak Miller index (hkI) value of 009.

If the spray coating process is repeated to stack the semiconductor layer 130, the crystals may be sorted and aligned from the bottom to the top as the thin semiconductor layer is stacked several times.

The semiconductor layer 130 is stacked by the spray coating method to form the semiconductor layer 130 including the crystallized oxide semiconductor layer, and the source electrode 171 and the drain electrode 172 are formed on the second region 132 and the third region 133 of the semiconductor layer 130, thereby forming the thin film transistor as shown in FIG. 2.

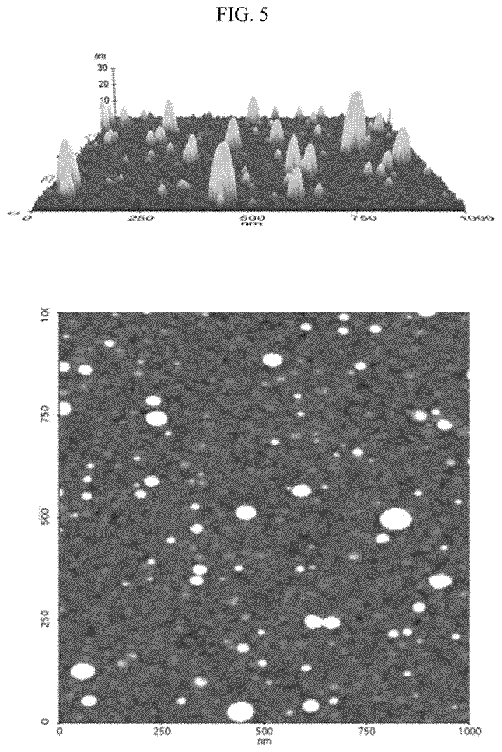

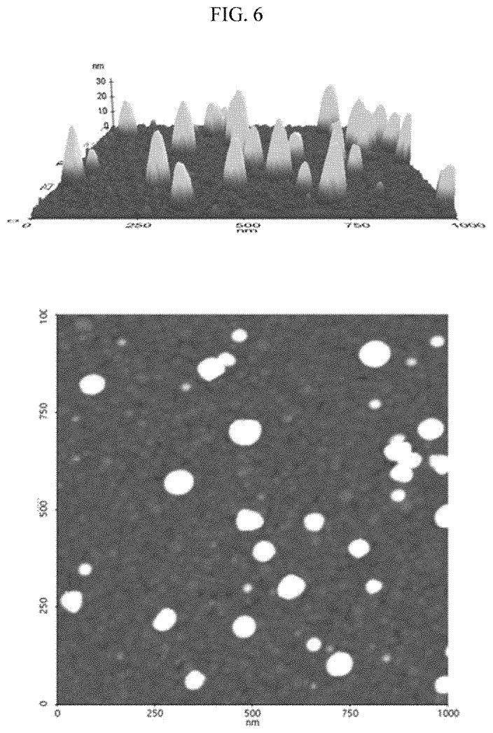

Now, a result of an experimental example is described with reference to FIG. 5 to FIG. 8. FIG. 5 to FIG. 8 are transmission electron micrographs showing a result of an experimental example.

In the present experimental example, an oxide semiconductor layer was stacked on a substrate by a spray coating, and a crystallization process of the oxide semiconductor layer was measured while repeating the spray coating process.

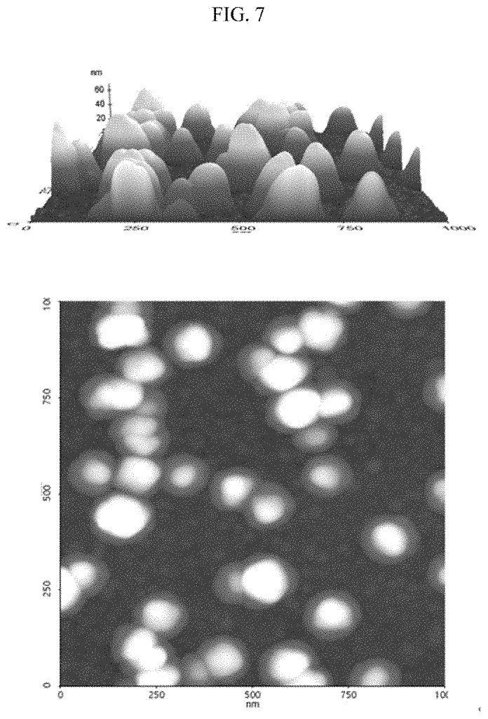

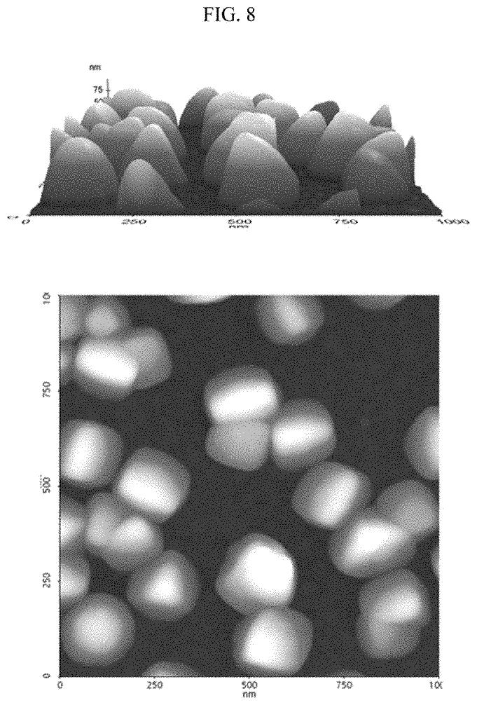

FIG. 5 shows a result of performing the spray coating process once for stacking the oxide semiconductor layer, FIG. 6 shows a result of performing the spray coating process twice for stacking the oxide semiconductor layer, FIG. 7 shows a result of performing the spray coating process 5 times for stacking the oxide semiconductor layer, and FIG. 8 shows a result of performing the spray coating process 15 times for stacking the oxide semiconductor layer. In FIG. 5 to FIG. 8, a figure above shows the result of measuring the surface of the oxide semiconductor layer formed by the spray coating process from the top side, and a figure below shows the result of measuring the surface of the oxide semiconductor layer formed by the spray coating process from the top.

Referring to FIG. 5 to FIG. 8, it may be confirmed that crystal nuclei are formed at the beginning of the spray coating process for stacking the oxide semiconductor layer, and the crystals grow centered on the crystal nuclei as the spray coating process for stacking the oxide semiconductor layer proceeds.

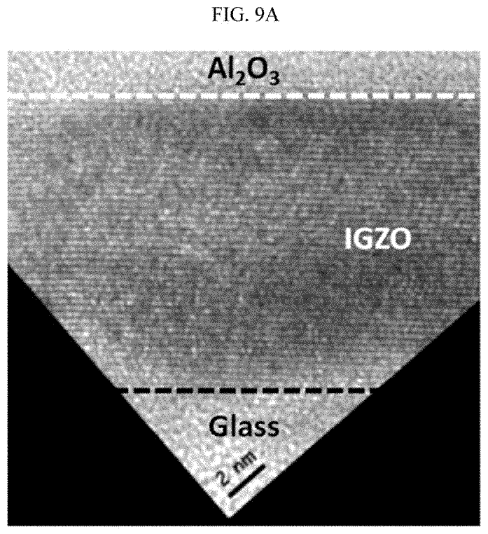

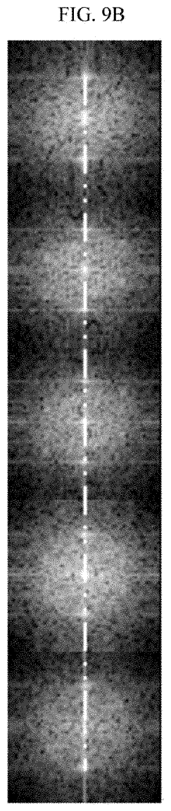

Another experimental example is described with reference to FIG. 9A and FIG. 9B. FIG. 9A and FIG. 9B are transmission electron micrographs showing a result of another experimental example.

In the present experimental example, the oxide semiconductor layer of the crystallized IGZO was formed by the spray coating method on a glass substrate Glass, an insulating layer of aluminum oxide (Al₂O₃) was stacked thereon, the cross-section of the oxide semiconductor layer was measured by a Transmission Electron Microscope (TEM:), and a result is shown in FIG. 9A and FIG. 9B.

FIG. 9A is a cross-section of a part of a substrate, an oxide semiconductor layer, and an insulating layer, and FIG. 9B is an enlarged cross-section of a part of an oxide semiconductor layer of FIG. 9A.

Referring to FIG. 9A, it may be seen that the oxide semiconductor layer is stacked to have crystals, and referring to FIG. 9B, it may be seen that the central axis of the crystal of the oxide semiconductor layer is formed to be aligned in the vertical direction.

Through the experimental examples described with reference to FIG. 5 to FIG. 8 and FIG. 9A and FIG. 9B, like the thin film transistor and the manufacturing method of the thin film transistor according to the above-described embodiments, it may be confirmed that when the oxide semiconductor layer is stacked by the spray coating process, the crystal nucleus is formed in the semiconductor layer at the beginning of the process, the crystals are crystallized by being grown around the crystal nucleus while the additional semiconductor layer is stacked on the crystal nucleus by the spray coating process, and as these processes are repeated, the crystallized oxide semiconductor layer may be formed in which the central axes of the crystals are aligned from the bottom toward the top of the semiconductor layer.

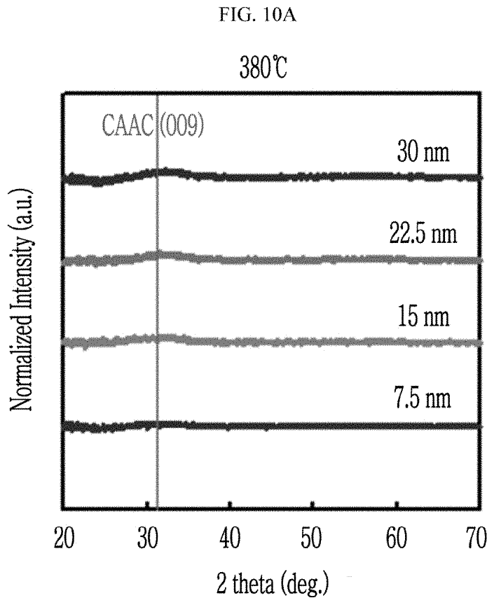

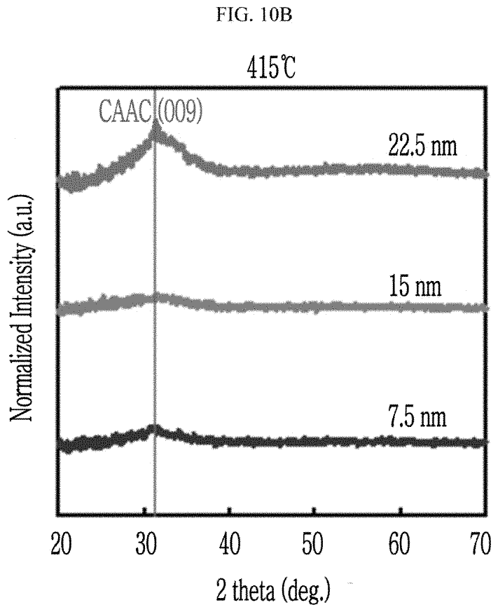

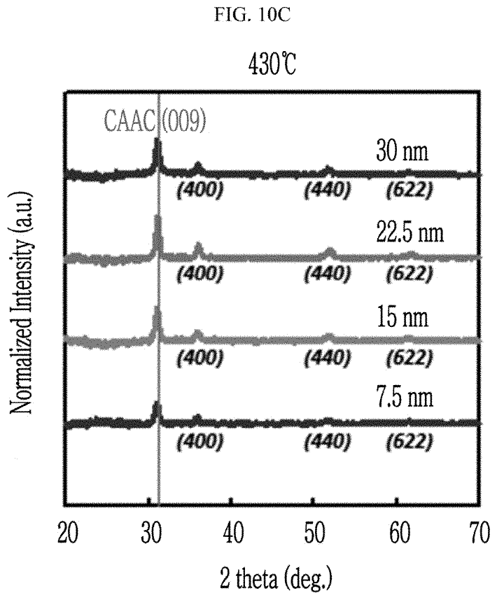

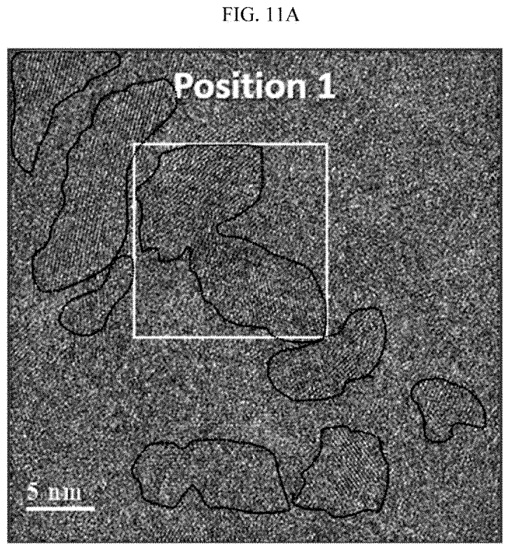

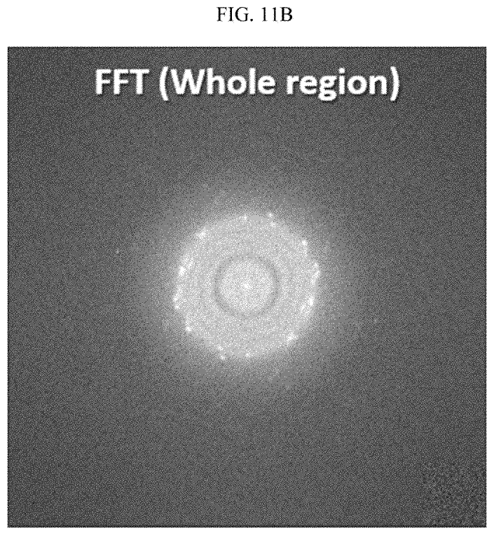

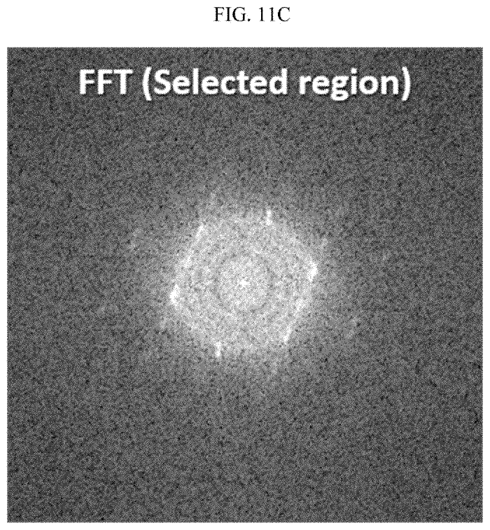

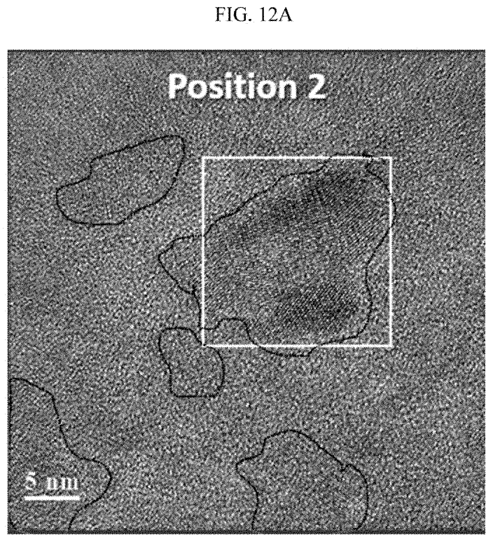

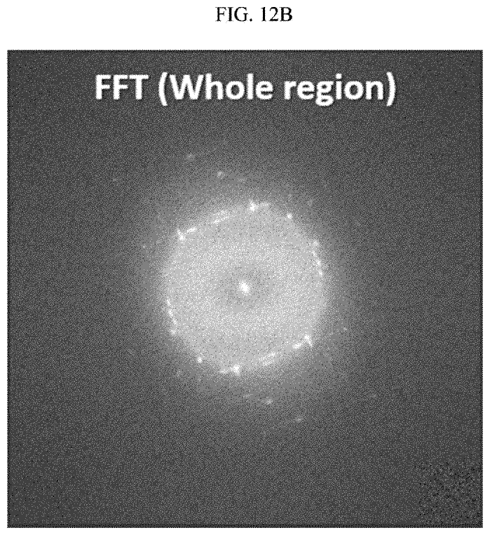

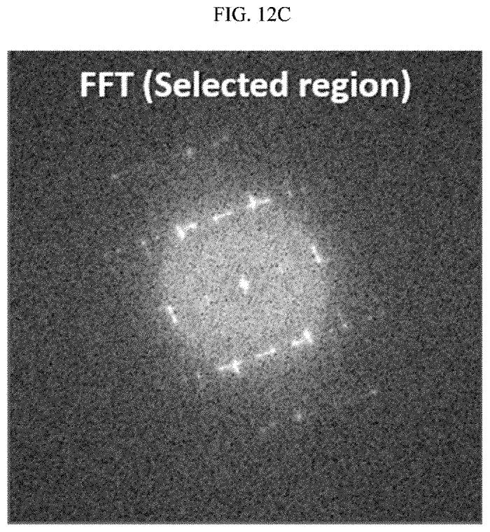

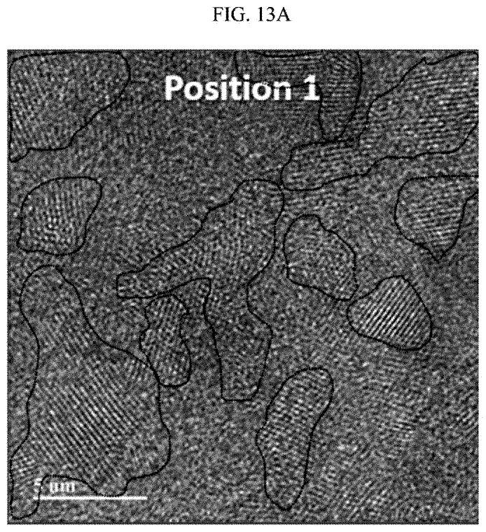

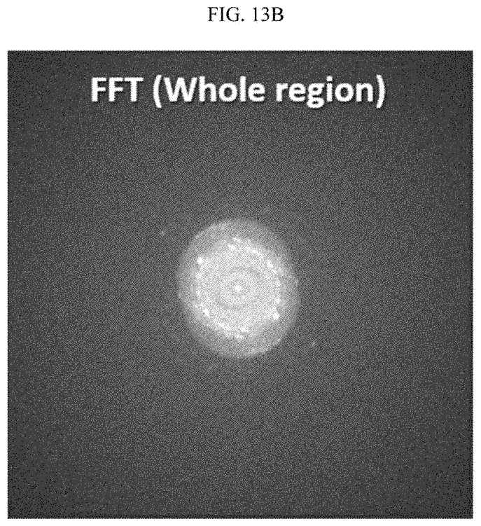

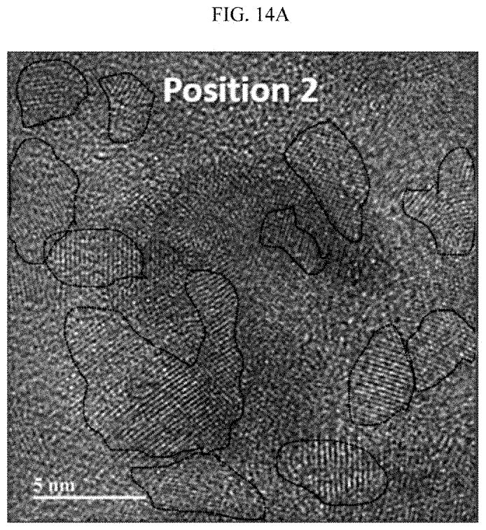

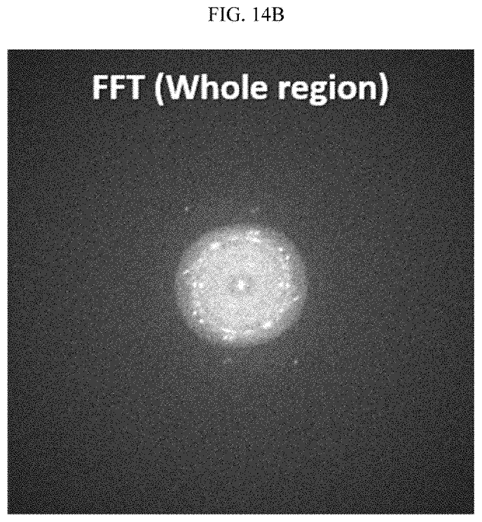

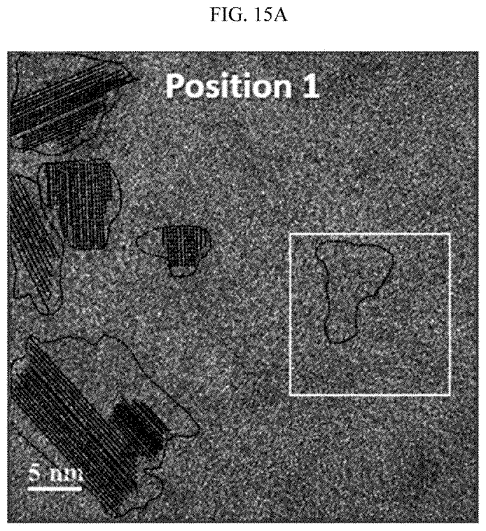

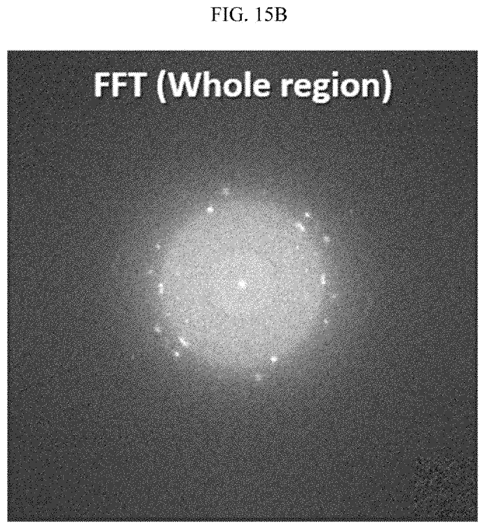

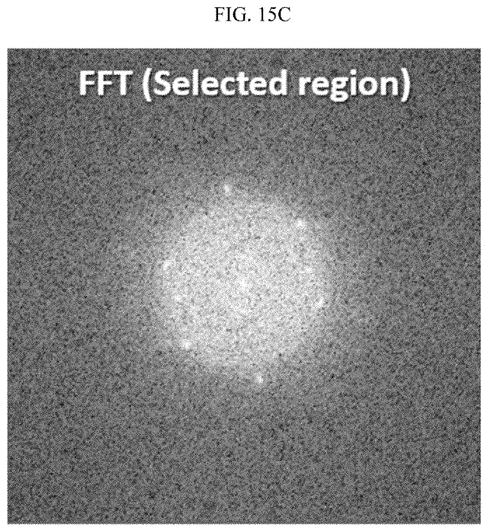

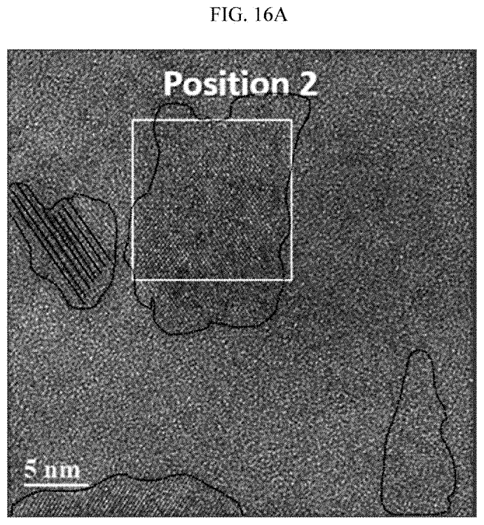

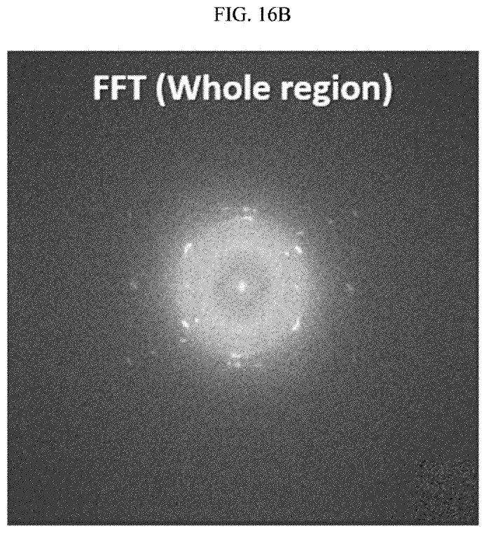

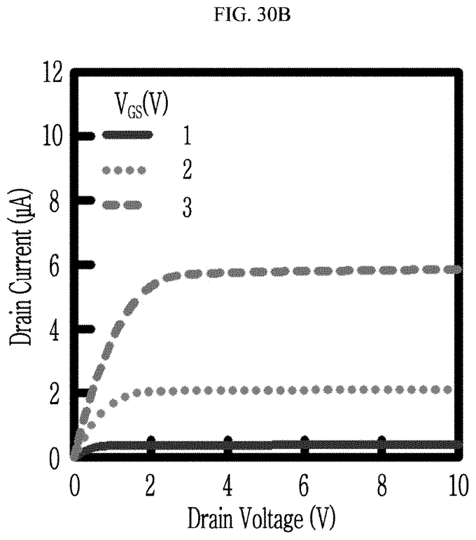

Next, another experimental example is described with reference to FIG. 10A to FIG. 100, FIG. 11A to FIG. 11C, FIG. 12A to FIG. 12C, FIG. 13A and FIG. 13B, FIG. 14A and FIG. 14B, FIG. 15A to FIG. 15C, FIG. 16A to FIG. 16C, FIG. 17A to FIG. 17C, and FIG. 18A to FIG. 18C. FIG. 10A to FIG. 100 are graphs showing a result of another experimental example, and FIG. 12A to FIG. 12C, FIG. 13A and FIG. 13B, FIG. 14A and FIG. 14B, FIG. 15A to FIG. 15C, FIG. 16A to FIG. 16C, FIG. 17A to FIG. 17C, and FIG. 18A to FIG. 18C are views showing an image showing a result of another experimental example.

In the present experimental example, like the manufacturing method of the thin film transistor according to the embodiment, IGZO (Indium-Gallium-Zinc-Oxide) of an oxide semiconductor layer was stacked on a glass substrate by a spray coating method. Together with Ammonium acetate (CH3CO2NH4) (AA) as a stabilizer in 2-Methoxyethanol (CH3OCH2CH2OH) of a volatile solvent, a solution in which Indium(III) chloride (InCl₃) of an indium (In) precursor, Gallium(III) nitrate hydrate (Ga NO₃₃·xH₂O) of a gallium (Ga) precursor, Zinc acetate dehydrate (Zn(CH₃OOO)₂·2H₂O) of a zinc (Zn) precursor are mixed at 1:1:1 was sprayed along with a carrier gas such as nitrogen and the volatile solvent was evaporated to form IGZO.

At this time, for a first case (case 1) carried out under a temperature of about 380° C., a second case (case 2) carried out under a temperature of about 415° C., and a third case (case 3) carried out under a temperature of about 430° C., so an IGZO layer of the semiconductor layer was formed.

In the first case (case 1), the second case (case 2) and the third case (case 3), XRD analysis results of cases in which the IGZO layer, which is the semiconductor layer, is stacked at about 7.5 nm, about 15 nm, about 22.5 nm, and about 30 nm were shown in FIG. 10A to FIG. 100 as a graph. FIG. 10A shows the result of the first case (case 1), FIG. 10B shows the result of the second case (case 2), and FIG. 100 shows the result of the third case (case 3).

In addition, a transmission electron microscopy (TEM) image was measured on the upper surface of the semiconductor layer for the first case (case 1), the second case (case 2), the third case (case 3), and a fourth case (case 4) performed under a temperature of about 330° C., and results thereof were shown in FIG. 11A to FIG. 11C, FIG. 12A to FIG. 12C, FIG. 13A and FIG. 13B, FIG. 14A and FIG. 14B, FIG. 15A to FIG. 15C, FIG. 16A to FIG. 16C, FIG. 17A to FIG. 17C, and FIG. 18A to FIG. 18C.

FIG. 11A to FIG. 11C and FIG. 12A to FIG. 12C show the transmission electron microscope (TEM) image result of the fourth case (case 4) carried out under a temperature of about 330° C., FIG. 13A and FIG. 13B and FIG. 14A and FIG. 14B show the transmission electron microscope (TEM) image result of the first case (case 1) carried out under a temperature of about 380° C., FIG. 15A to FIG. 15C and FIG. 16A to FIG. 16C show the transmission electron microscope (TEM) image result of the second case (case 2) carried out under a temperature of about 415° C., and FIG. 17A to FIG. 17C and FIG. 18A to FIG. 18C show the transmission electron microscope (TEM) image result of the third case (case 3) carried out under a temperature of about 430° C.

Referring to FIG. 10A to FIG. 100, like the manufacturing method of the thin film transistor according to the embodiment, for the cases of stacking the IGZO of the oxide semiconductor layer by the spray coating method, as the XRD (X-ray diffraction) result, it may be confirmed that the crystal of IGZO has a main peak value at a 2theta (2θ) value of about 31.09° and a C Axis Aligned Crystal (CAAC) with a main peak Miller index (hkI) value of 009, and the main peak value of XRD (X-ray diffraction) became larger as the thickness of the IGZO as the oxide semiconductor layer became thicker.

Accordingly, like the thin film transistor and the manufacturing method of the thin film transistor according to the above-described embodiments, it may be confirmed that, when the spray coating process is performed, the crystal nucleus is formed in the semiconductor layer at the beginning of the process, and as the additional semiconductor layer is stacked on the crystal nucleus by the spray coating process, the crystal grows around the crystal nucleus and is crystallized, and as these processes are repeated, the oxide semiconductor layer of which the central axes of the crystals are aligned from the bottom to the top of the semiconductor layer may be formed.

FIG. 11A to FIG. 11C and FIG. 12A to FIG. 12C are transmission electron microscope (TEM) image results measured at two different positions (position 1, position 2) of the crystallized IGZO formed in the fourth case (case 4) carried out under a temperature of about 330° C. FIG. 11A and FIG. 12A show the TEM images of the first position (position 1) and the second position (position 2), FIG. 11B and FIG. 12B show FFT images obtained by transforming the TEM image by FFT (Fast Fourier Transformation), and FIG. 11C and FIG. 12C show FFT images obtained by transforming the TEM image FFT for a partial region of FIG. 11A and FIG. 12A by FFT.

FIG. 11A and FIG. 12A show the position of the crystallized crystal nuclei as a line. It may be confirmed that the crystals of IGZO formed by growing the crystals along these crystal nuclei, as shown in FIG. 11B and FIG. 110, and FIG. 12B and FIG. 12C, have almost the same crystal as each other, and as described above, it may be confirmed that they are the C Axis Aligned Crystal (CAAC) of which the XRD (X-ray diffraction) Miller index (hkI) value is 009.

FIG. 13A and FIG. 13B and FIG. 14A and FIG. 14B are transmission electron microscope (TEM) image results measured at two different positions (position 1, position 2) of the crystallized IGZO formed in the first case (case 1) carried out under a temperature of about 380° C. FIG. 13A and FIG. 14A show TEM images of the first position (position 1) and the second position (position 2), and FIG. 13B and FIG. 114B show an FFT image obtained by transforming a TEM image by FFT (Fast Fourier Transformation).

FIG. 13A and FIG. 14A show the positions of the crystallized crystal nuclei with lines. It may be confirmed that the crystals of IGZO formed by growing the crystals along these crystal nuclei have almost the same crystal form as each other as shown in FIG. 13B and FIG. 14B, and as described above, are the C Axis Aligned Crystal (CAAC) having the X-ray diffraction (XRD) Miller index (hkI) value of 009 (CAAC).

It may be confirmed that the crystal form shown in FIG. 13B and FIG. 14B was similar to the crystal form of FIG. 11B and FIG. 11C and FIG. 12B and FIG. 12C as the result of the fourth case (case 4).

FIG. 15A to FIG. 15C, and FIG. 16A to FIG. 16C are transmission electron microscope (TEM) image results measured at two different positions (position 1, position 2) of the crystallized IGZO formed in the second case (case 2) carried out under a temperature of about 415° C. FIG. 15A and FIG. 16A show TEM images of the first position (position 1) and the second position (position 2), FIG. 15B and FIG. 16B show FFT images obtained by transforming a TEM image by FFT (Fast Fourier Transformation), and FIG. 15C and FIG. 16C show FFT images obtained by transforming a TEM image for a partial region of FIG. 15A and FIG. 16A by FFT.

In FIG. 15A and FIG. 16A, the positions of the crystallized crystal nuclei are shown as lines. It may be confirmed that the crystals of IGZO formed by growing the crystals along these crystal nuclei have almost the same crystal as each other as shown in shown in FIG. 15B and FIG. 15C, and FIG. 16B and FIG. 16C, and It may be confirmed that they are the C Axis Aligned Crystal (CAAC) having the X-ray diffraction (XRD) Miller index (hkI) value of 009, as described above.

It may be confirmed that the crystal form shown in FIG. 15B and FIG. 15C, and FIG. 16B and FIG. 16C is similar to the crystal form of FIG. 11B and FIG. 11C, and FIG. 12B and FIG. 12C of the result of the above fourth case (case 4) and the crystal form of FIG. 13B and FIG. 14B of the result of the first case (case 1).

FIG. 17A to FIG. 17C and FIG. 18A to FIG. 18C are transmission electron microscope (TEM) image results measured at two different positions (position 1, position 2) of the crystallized IGZO formed in the third case (case 3) conducted under a temperature of about 430° C. FIG. 17A and FIG. 18A shows the TEM images of the first position (position 1) and the second position (position 2), FIG. 17B and FIG. 18B show the FFT images obtained by transforming the TEM images by FFT (Fast Fourier Transformation), and FIG. 17C and FIG. 18C show the FFT images obtained by transforming the TEM images by FFT (Fast Fourier Transformation) for a partial region of FIG. 17A and FIG. 18A.

In FIG. 17A and FIG. 18A, the position of crystal nuclei to be crystallized is shown as a line. It may be confirmed that the crystals of IGZO formed by growing the crystals along these crystal nuclei have almost the same crystal as each other as shown in shown in FIG. 17B and FIG. 17C, and FIG. 18B and FIG. 18C, and it may be confirmed that they are the C Axis Aligned Crystal (CAAC) having the X-ray diffraction (XRD) Miller index (hkI) value of 009, as described above.

It may be confirmed that the crystal form shown in FIG. 17B and FIG. 17C, and FIG. 18B and FIG. 18C is similar to the crystal form of FIG. 11B and FIG. 11C, and FIG. 12B and FIG. 12C of the result of the above fourth case (case 4), the crystal form of FIG. 13B and FIG. 14B of the result of the first case (case 1), and the crystal form of FIG. 15B and FIG. 15C, and FIG. 16B and FIG. 16C of the result of the second case (case 2).

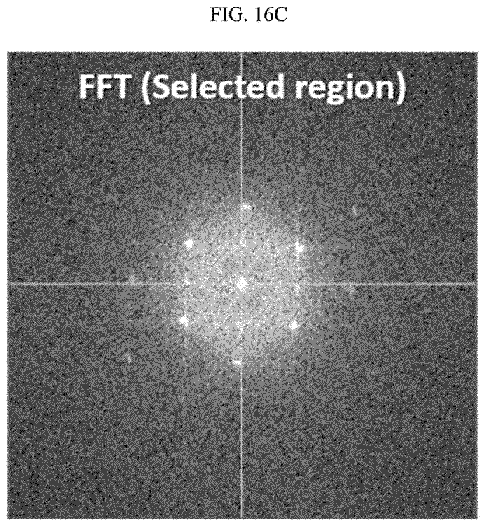

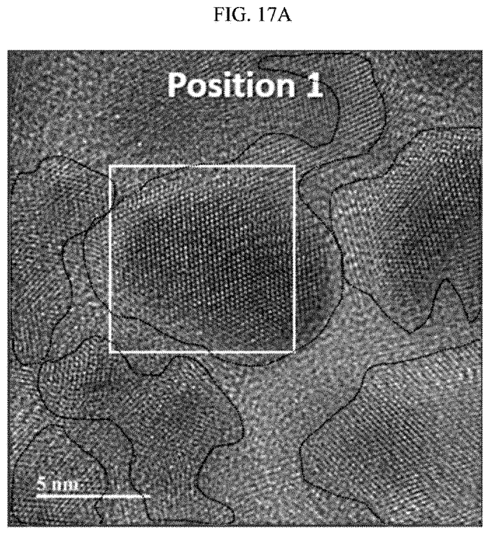

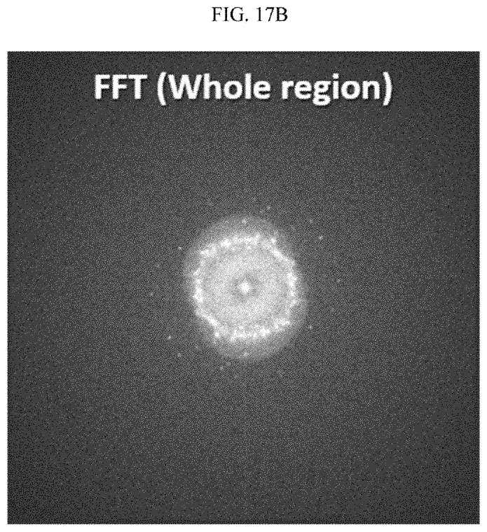

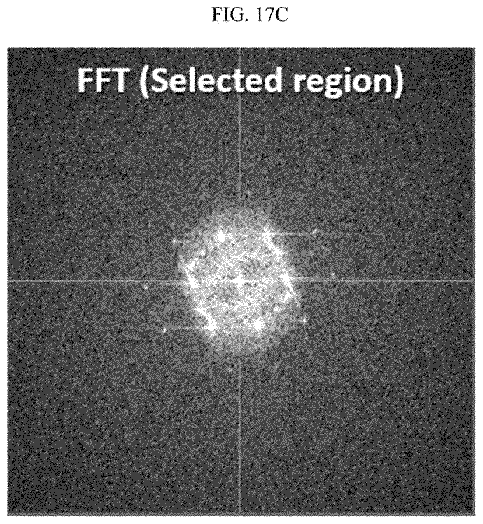

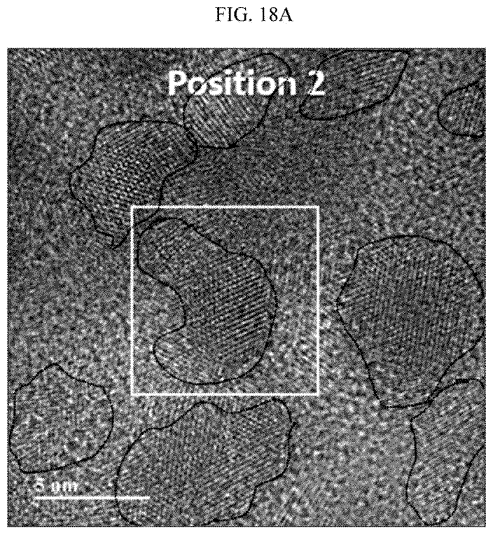

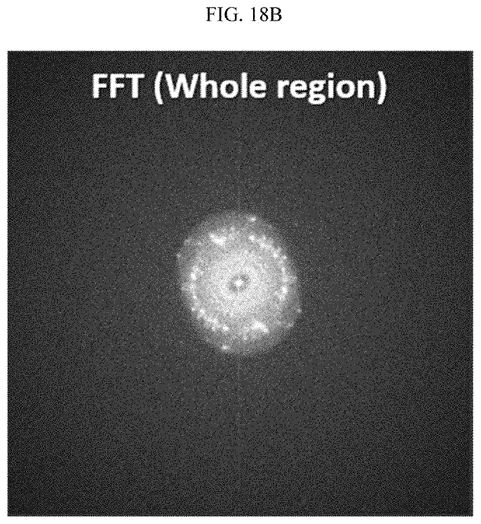

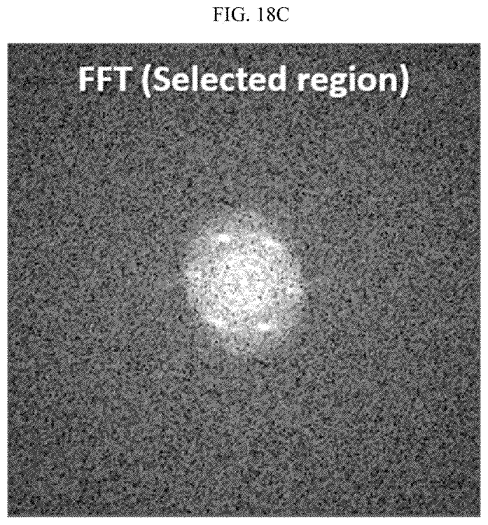

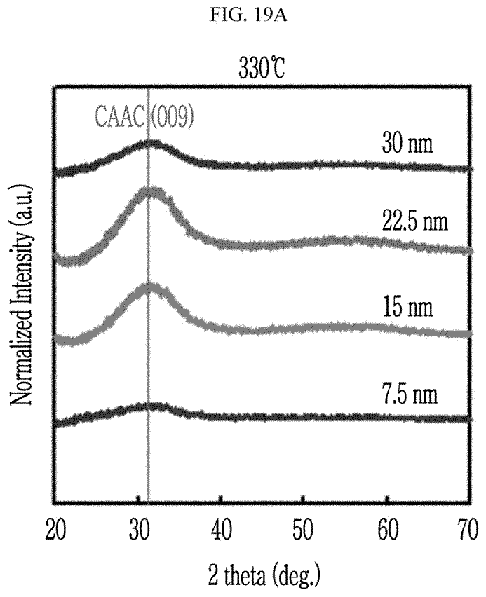

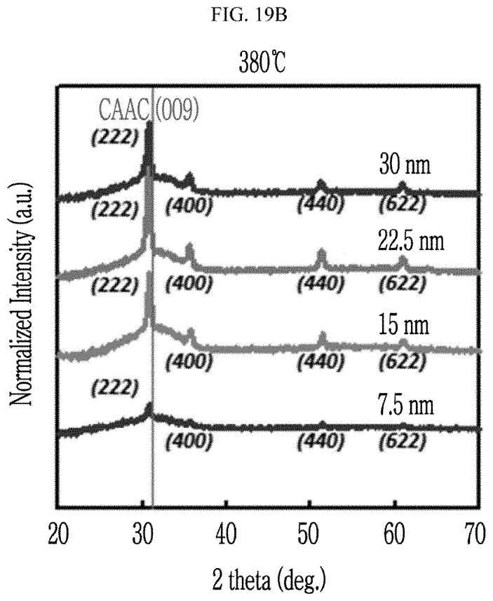

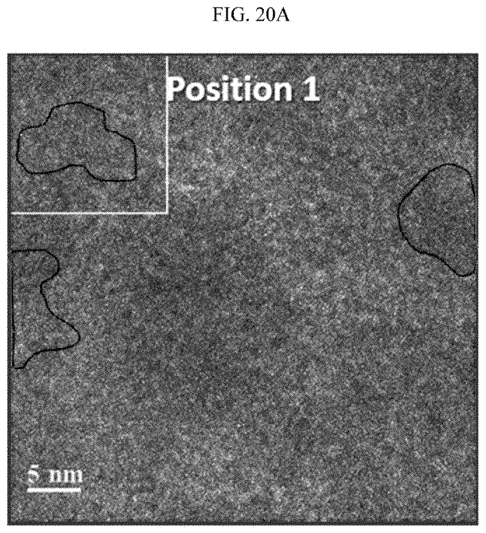

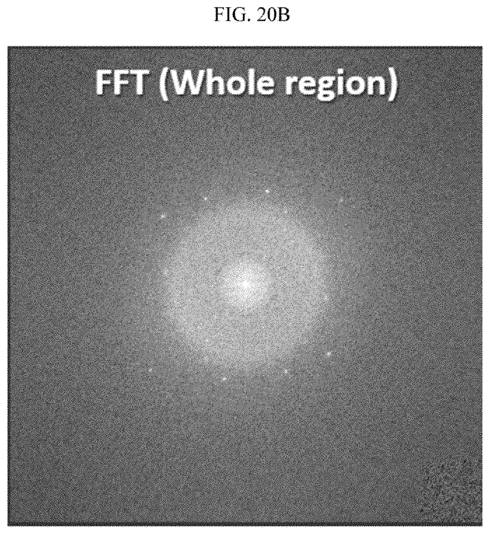

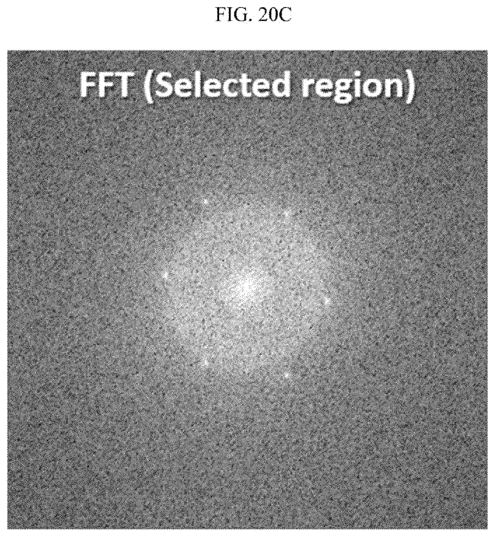

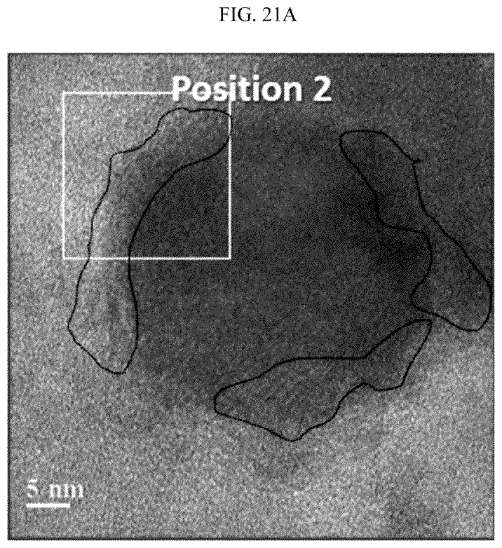

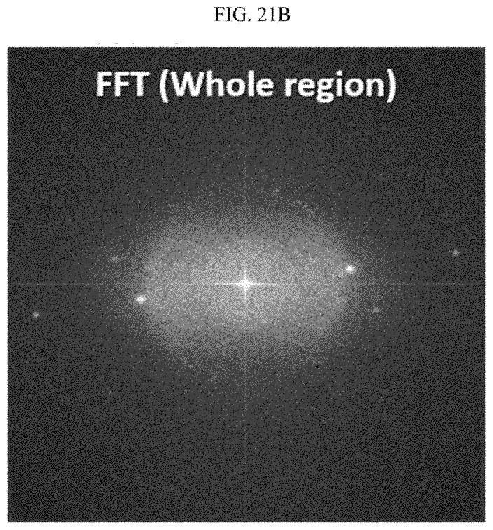

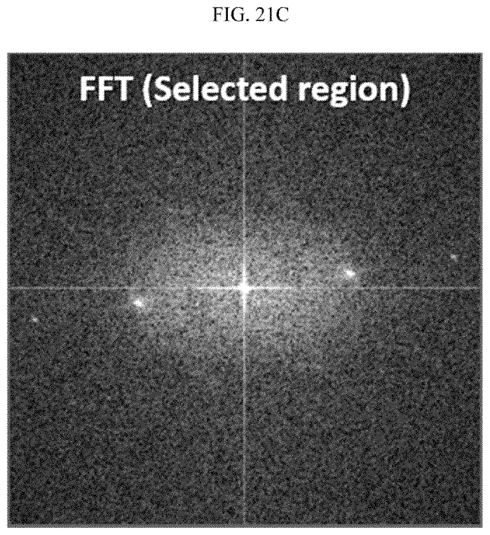

Next, the result of another experimental example is described with reference to FIG. 19A and FIG. 19B, FIG. 20A to FIG. 20C, and FIG. 21A to FIG. 21C. FIG. 19A and FIG. 19B are graphs showing a result of another experimental example, and FIG. 20A to FIG. 20C and FIG. 21A to FIG. 21C are images showing a result of another experimental example.

In this experimental example, IZTO (Indium-Zinc-Tin-Oxide) of an oxide semiconductor layer is stacked on a glass substrate by the spray coating method. Together with Ammonium acetate (CH3CO2NH4) (AA) as a stabilizer in 2-Methoxyethanol (CH3OCH2CH2OH) of a volatile solvent, a solution in which Indium(III) chloride (InCl₃) of an indium (In) precursor, Zinc acetate dehydrate (Zn (CH₃COO)₂·2H₂O) of a zinc(Zn) precursor and Tin(II) chloride dihydrate (SnCl₂·2H₂O) of a tin (Sn) precursor are mixed at 1:1:1 was sprayed along with a carrier gas such as nitrogen and the volatile solvent was evaporated to form IZTO.

At this time, for a first case (case 1) carried out under a temperature of about 330° C. and a second case (case 2) carried out under a temperature of about 380° C., an IZTO layer of the semiconductor layer was formed

In the first case (case 1) and the second case (case 2), XRD analysis results of cases in which the IZTO layer of the semiconductor layer is stacked at about 7.5 nm, about 15 nm, about 22.5 nm, about 30 nm were shown in FIG. 19A and FIG. 19B as a graph. FIG. 19A shows the result of the first case (case 1), and FIG. 19B shows the result of the second case (case 2).

In addition, a transmission electron microscope (TEM) image was measured on the upper surface of the semiconductor layer for the first case (case 1) carried out under a temperature of about 330° C., and the result is shown in FIG. 20A to FIG. 20C, and FIG. 21A to FIG. 21C.

Referring to FIG. 19A and FIG. 19B, like the manufacturing method of the thin film transistor according to the embodiment, for the case of stacking the IZTO of the oxide semiconductor layer by the spray coating method, as the XRD (X-ray diffraction) result, it may be confirmed that the crystal of IZTO has a main peak value at a 2theta (2θ) value of about 31.09° and a C Axis Aligned Crystal (CAAC) with a main peak Miller index (hkI) value of 009, and the main peak value of XRD (X-ray diffraction) became larger as the thickness of the IZTO as the oxide semiconductor layer became thicker.

Accordingly, like the thin film transistor and the manufacturing method of the thin film transistor according to the above-described embodiments, it may be confirmed that, when the spray coating process is performed, the crystal nucleus is formed in the semiconductor layer at the beginning of the process, and as the additional semiconductor layer is stacked on the crystal nucleus by the spray coating process, the crystal grows around the crystal nucleus and is crystallized, and as these processes are repeated, the oxide semiconductor layer of which the central axes of the crystals are aligned from the bottom to the top of the semiconductor layer may be formed.

FIG. 20A to FIG. 20C, and FIG. 21A to FIG. 21C are transmission electron microscope (TEM) image results measured at two different positions (position 1, position 2) of the crystallized IZTO formed in the first case (case 1) carried out under a temperature of about 330° C. FIG. 20A and FIG. 21A show the TEM images of the first position (position 1) and the second position (position 2), FIG. 20B and FIG. 21B show an FFT image obtained by transforming the TEM image by FFT (Fast Fourier Transformation), and FIG. 20C and FIG. 21C show an FFT image obtained by transforming the TEM image FFT for a partial region of FIG. 20A and FIG. 21A

FIG. 20A and FIG. 21A show the position of the crystallized crystal nuclei as a line. Referring to FIG. 20B and FIG. 20C, and FIG. 21B and FIG. 21C, in this experimental example, it may be confirmed that the crystals of IZTO formed by growing the crystals along these crystal nuclei, like the above-described experimental example, have almost the same crystal as the case formed of the semiconductor layer of IGZO, as described above, it may be confirmed that they are the C Axis Aligned Crystal (CAAC) of which the XRD (X-ray diffraction) Miller index (hkI) value is 009.

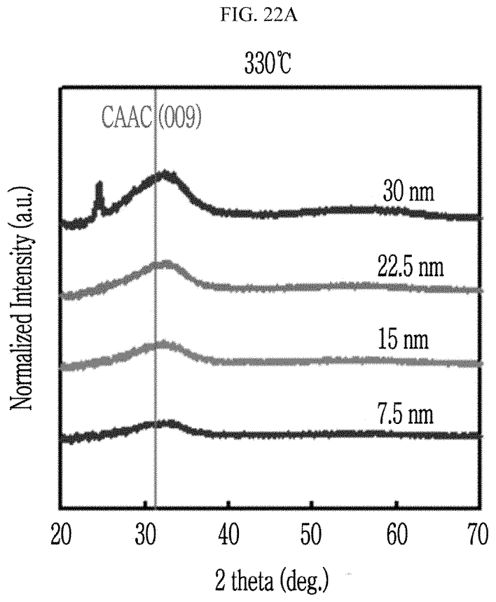

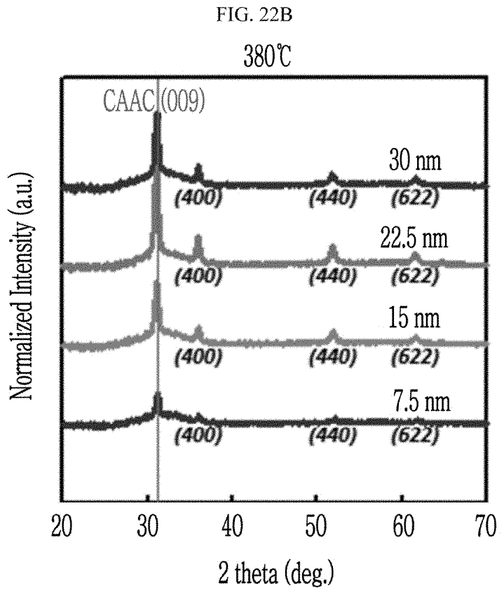

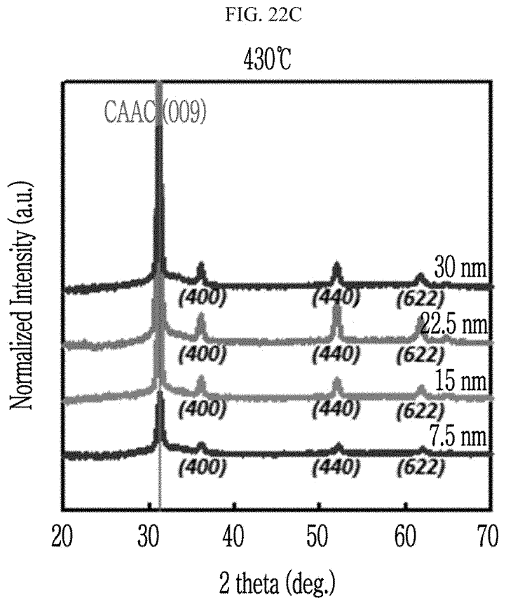

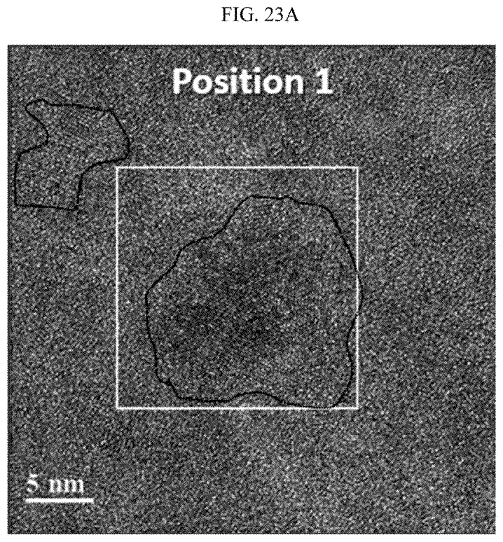

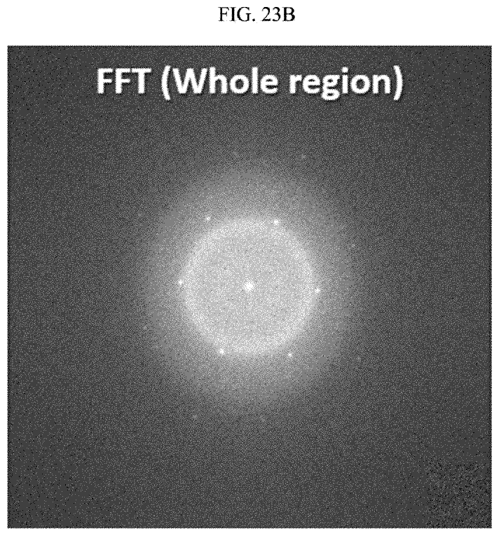

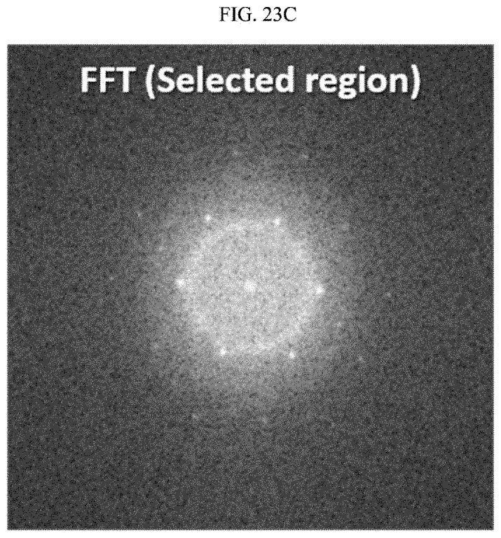

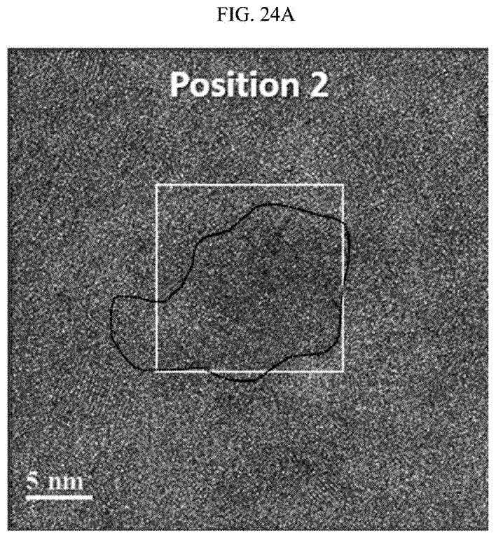

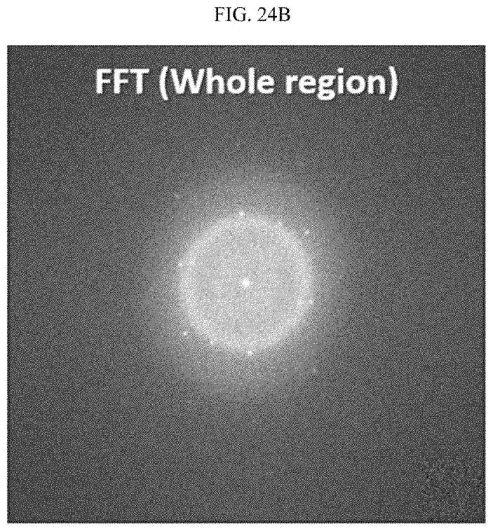

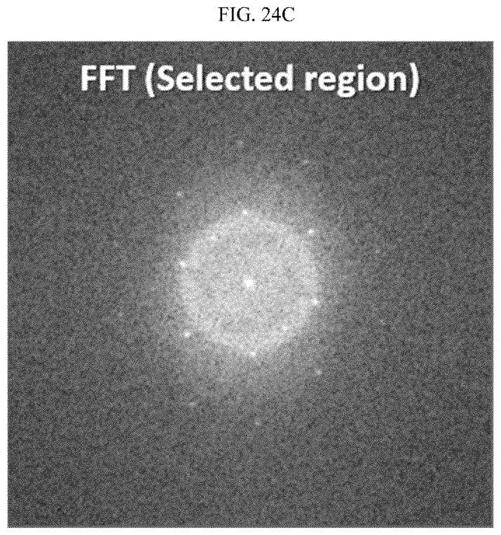

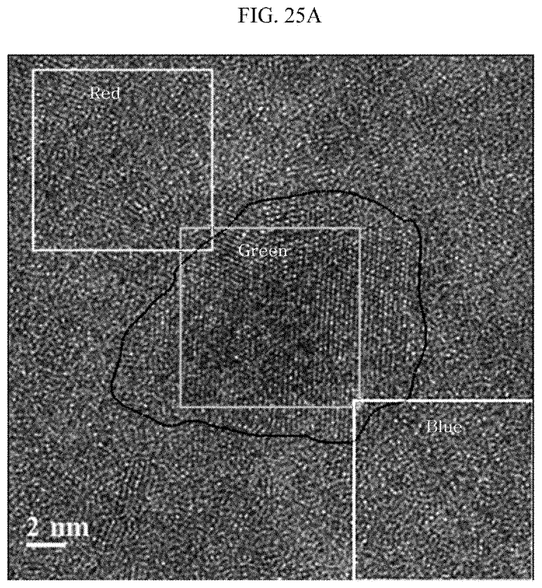

Next, a result of another experimental example is described with reference to FIG. 22A to FIG. 22C, FIG. 23A to FIG. 23C, FIG. 24A to FIG. 24C, and FIG. 25A to FIG. 25E. FIG. 22A to FIG. 22C are graphs showing a result of another experimental example, and FIG. 23A to FIG. 23C, FIG. 24A to FIG. 24C, and FIG. 25A to FIG. 25E are graphs showing a result of another experimental example.

In this experimental example, an IGZTO (Indium-Gallium-Zinc-Tin-Oxide) of the oxide semiconductor layer is stacked on a glass substrate by the spray coating method. Together with Ammonium acetate (CH3CO2NH4) (AA) as a stabilizer in 2-Methoxyethanol (CH3OCH2CH2OH) as a volatile solvent, a solution in which Indium(III) chloride (InCl₃) of the indium (In) precursor, Gallium(III) nitrate hydrate (Ga NO₃₃·xH₂O) of the gallium (Ga) precursor, Zinc acetate dehydrate (Zn(CH₃COO)₂·2H₂O) of the zinc (Zn) precursor, Tin(II) chloride dihydrate (SnCl₂·2H₂O) of the tin (Sn) precursor are mixed at 4:1:4:3 was sprayed along with a carrier gas such as nitrogen and the volatile solvent was evaporated to form IGZTO.

At this time, the semiconductor of an IGZTO layer was formed for the first case (case 1) conducted under a temperature of about 330° C. (case 1), the second case (case 2) performed under a temperature of about 380° C. (case 2), and the third case (case 3) performed under a temperature of about 430° C.

In the first case (case 1), the second case (case 2), and the third case (case 3), the XRD analysis results of the cases in which the semiconductor layer of the IGZTO layers were stacked at about 7.5 nm, about 15 nm, about 22.5 nm, and about 30 nm are shown in FIG. 22A to FIG. 22C as a graph. FIG. 22A shows the result of the first case (case 1), FIG. 22B shows the result of the second case (case 2), and FIG. 22C shows the result of the third case (case 3).

In addition, for the first case (case 1) conducted under a temperature of about 330° C., a transmission electron microscope (TEM) image was measured on the upper surface of the IGZTO layer, which is the semiconductor layer, and the result thereof is shown in FIG. 23A to FIG. 23C, FIG. 24A to FIG. 24C, and FIG. 25A to FIG. 25E.

Referring to FIG. 22A to FIG. 22C, like the manufacturing method of the thin film transistor according to the embodiment, for the case of stacking the IGZTO of the oxide semiconductor layer by the spray coating method, as the XRD (X-ray diffraction) result, it may be confirmed that the crystal of IGZO has a main peak value at a 2theta (2θ) value of about 31.09° and a C Axis Aligned Crystal (CAAC) with a main peak Miller index (hkI) value of 009, and the main peak value of XRD (X-ray diffraction) became larger as the thickness of the IGZTO as the oxide semiconductor layer became thicker.

Accordingly, like the thin film transistor and the manufacturing method of the thin film transistor according to the above-described embodiments, it may be confirmed that, when the spray coating process is performed, the crystal nucleus is formed in the semiconductor layer at the beginning of the process, as the additional semiconductor layer is stacked on the crystal nucleus by the spray coating process, the crystal grows around the crystal nucleus and is crystallized, and as these processes are repeated, the oxide semiconductor layer of which the central axes of the crystals are aligned from the bottom to the top of the semiconductor layer may be formed.

FIG. 23A to FIG. 23C, and FIG. 24A to FIG. 24C are transmission electron microscope (TEM) image results measured at two different positions (position 1, position 2) of the crystallized IGZTO formed in the first case (case 1) carried out under a temperature of about 330° C. FIG. 23A and FIG. 24A show the TEM images of the first position (position 1) and the second position (position 2), FIG. 23B and FIG. 24B show FFT images obtained by transforming the TEM image by FFT (Fast Fourier Transformation), and FIG. 23C and FIG. 24C show FFT images obtained by transforming the TEM image FFT for a partial region of FIG. 23A and FIG. 24A.

FIG. 23A and FIG. 24A show the position of the crystallized crystal nuclei as a line. Referring to FIG. 23B and FIG. 23C, and FIG. 24B and FIG. 24C, in this experimental example, it may be confirmed that the crystals of IGZTO formed by growing the crystals along these crystal nuclei have almost the same crystal as that of the case of forming the semiconductor layer of the IGZO and the case forming of the semiconductor layer of IZTO like the above-described experimental examples, and as described above, it may be confirmed that they are the C Axis Aligned Crystal (CAAC) of which the XRD (X-ray diffraction) Miller index (hkI) value is 009.

FIG. 25A to FIG. 25E is a transmission electron microscope (TEM) image result of the crystallized IGZTO formed in the first case (case 1) carried out under a temperature of about 330° C. FIG. 25A is a TEM image of a third position, FIG. 25B shows an FFT image obtained by transforming the TEM image of FIG. 25A by FFT (Fast Fourier Transformation), and FIG. 25C to FIG. 25E show FFT images obtained by transforming TEM images for three regions of FIG. 25A by the FFT, respectively.

In FIG. 25A, the position of the crystallized crystal nuclei is shown as a line. Referring to FIG. 25B to FIG. 25E, it may be found that the crystal shapes measured in the various regions of the surface of the IGZTO of the semiconductor layer have almost the same shape. in this experimental example, it may be confirmed that the crystals of IGZTO formed by growing the crystals along these crystal nuclei have almost the same crystal as that of the case of forming the semiconductor layer of the IGZO and the case of forming of the semiconductor layer of IZTO like the above-described experimental examples, and as described above, it may be confirmed that they are the C Axis Aligned Crystal (CAAC) of which the XRD (X-ray diffraction) Miller index (hkI) value is 009.

As above-described, according to the above-described experimental examples, like the thin film transistor and the manufacturing method according to the present embodiment, by stacking the oxide semiconductor layer by the spray coating method at a temperature of about 300° C. or higher to form the thin film transistor including the crystallized oxide semiconductor layer, it may be confirmed that the thin film transistor including the semiconductor layer having the C Axis Aligned Crystal (CAAC) crystal with the X-ray diffraction (XRD) Miller index (hkI) value of 009 is formed.

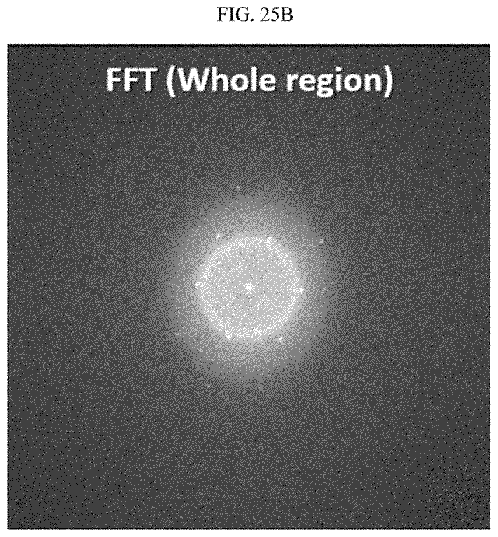

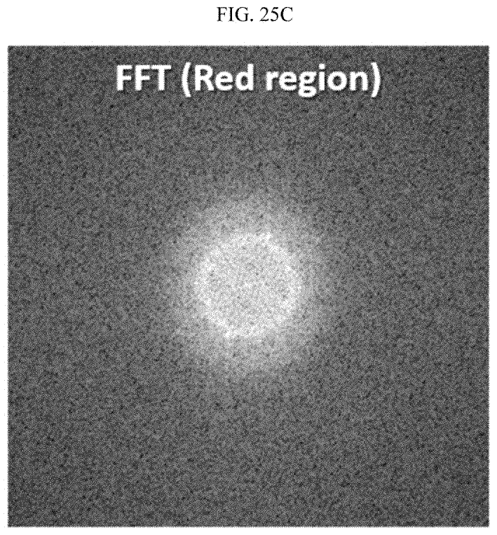

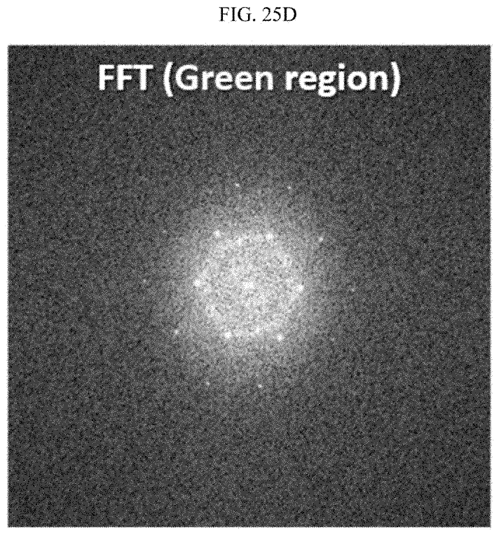

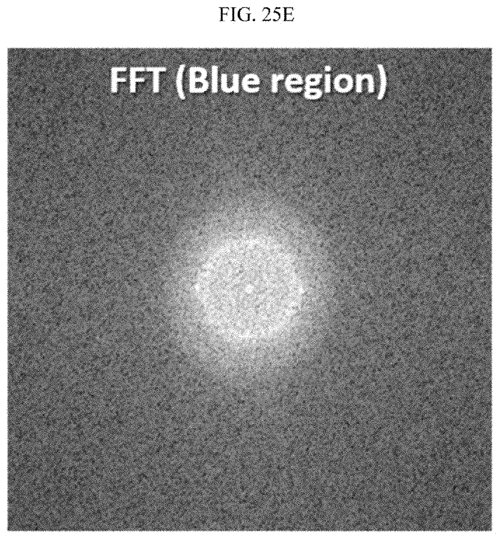

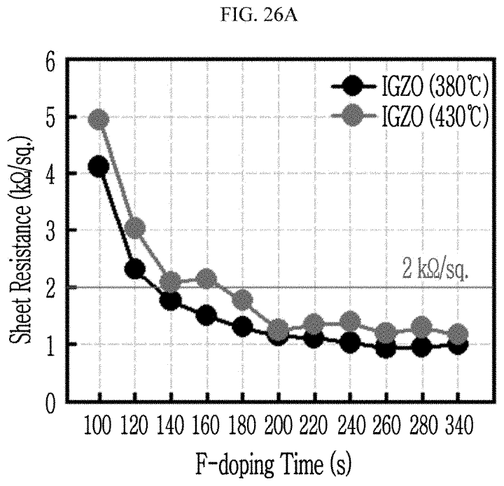

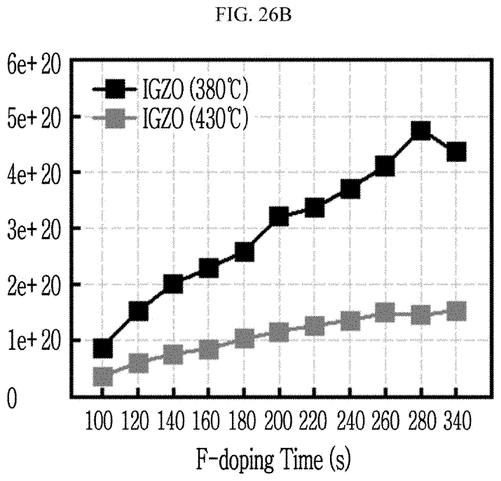

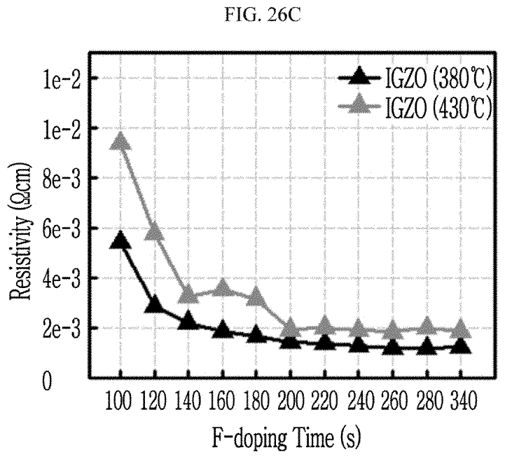

Another experimental example is described with reference to FIG. 26A to FIG. 26C. FIG. 26A to FIG. 26C are graphs showing a result of another experimental example.

In this experimental example, the IGZO of the crystallized oxide semiconductor layer formed by the spray coating method was formed, and then fluorine doping was carried out through fluorine plasma treatment on the semiconductor layer. At this time, for a first case (case 1) in which the IGZO layer was formed by the spray coating method at a temperature of about 380° C. and a second case (case 2) in which the IGZO layer was formed by the spray coating method at a temperature of about 430° C., sheet resistance, a carrier concentration, and resistivity of the IGZO layer were measured according to a fluorine doping time, and results thereof are shown in FIG. 26A to FIG. 26C.

In this experimental example, a fluorine plasma treatment was performed using an NF3:H2=30:20 (sccm) gas at a power of about 50 W, a pressure of about 70 mTorr, and at room temperature.

FIG. 26A shows a change of the sheet resistance of the IGZO layer depending on the fluorine doping time for the first case (case 1) and the second case (case 2), FIG. 26B shows a change of the carrier concentration of the IGZO layer depending on the fluorine doping time for the first case (case 1) and the second case (case 2), and FIG. 26C shows a change of the resistivity of the IGZO layer depending on the fluorine doping time for the first case (case 1) and the second case (case 2).

Referring to FIG. 26A, in both the first case (case 1) in which the IGZO layer was formed by the spray coating under a temperature of about 380° C. and the second case (case 2) in which the IGZO layer was formed by the spray coating under a temperature of about 430° C., it may be found that the sheet resistance value of the IGZO layer decreased as the fluorine doping time increased, converging to a value smaller than about 2 kΩ/sq.

Referring to FIG. 26B, in both the first case (case 1) in which the IGZO layer was formed by the spray coating under a temperature of about 380° C. and the second case (case 2) in which the IGZO layer was formed by the spray coating under a temperature of about 430° C., it may be found that the carrier concentration of the IGZO layer increased as the fluorine doping time increased.

Referring to FIG. 26C, in both the first case (case 1) in which the IGZO layer was formed by the spray coating under a temperature of about 380° C. and the second case (case 2) in which the IGZO layer was formed by the spray coating under a temperature of about 430° C., it may be found that the resistivity value of the IGZO layer decreased as the fluorine doping time increased, and then converged below a certain value.

As such, like the thin film transistor and the manufacturing method thereof according to the present embodiment, by stacking the oxide semiconductor layer by the spray coating under the temperature of about 300° C. or higher to form the thin film transistor including the crystallized oxide semiconductor layer and doping the impurities through fluorine plasma treatment, it may be found that the efficiency of the channel region of the semiconductor layer was improved.

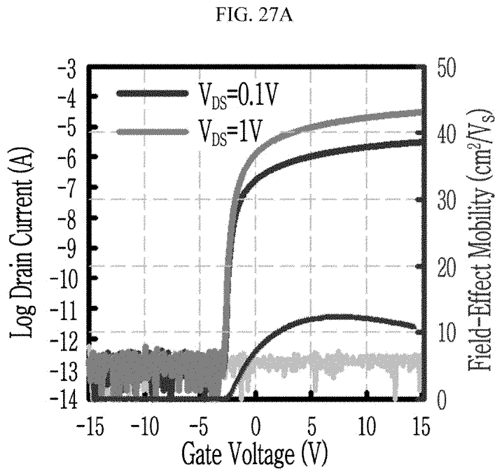

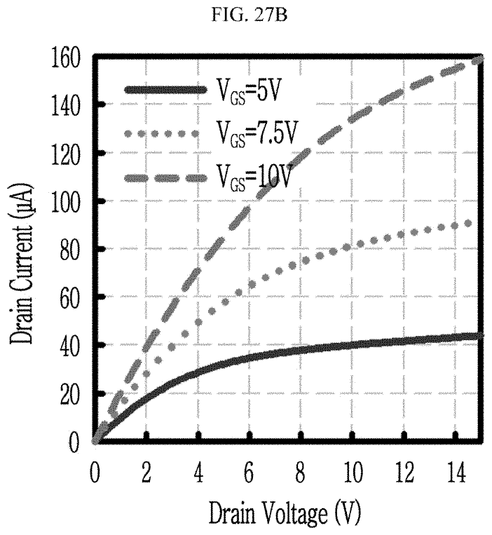

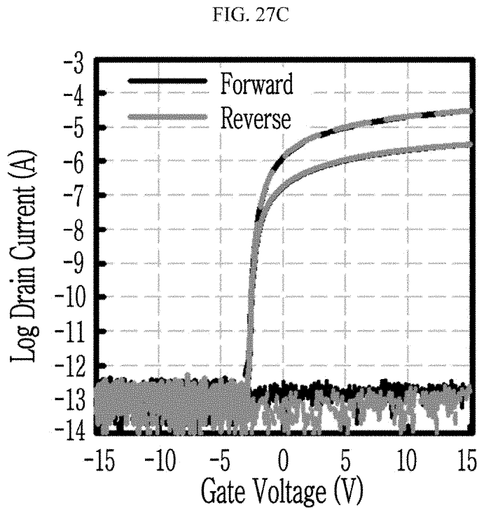

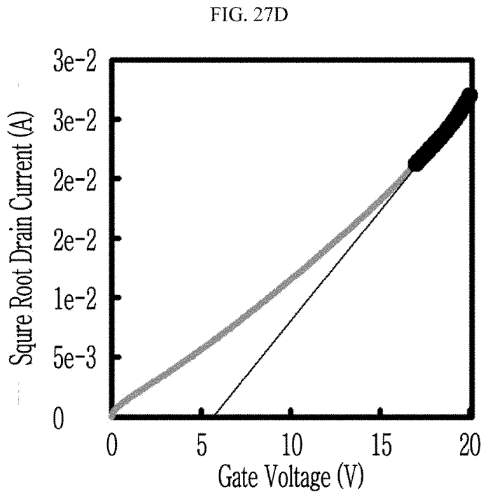

Next, another experimental example is described with reference to FIG. 27A to FIG. 27D. FIG. 27A to FIG. 27D are graphs showing a result of another experimental example.

In this experimental example, like the embodiment described with reference to FIG. 3A to FIG. 3C along with FIG. 1 above, after stacking the oxide semiconductor layer by the spray coating under the temperature of about 300° C. or higher to form the thin film transistor including the crystallized oxide semiconductor layer, a transfer curve, an output curve, a hysteresis curve, and a square root of a drain current of the formed thin film transistor are shown in FIG. 27A to FIG. 27D. In this case, the width of the channel region of the thin film transistor was about 20 μm and the length of the channel region was about 4 μm.

In addition, main characteristic values of the thin film transistor formed in this experimental example were measured and shown in Table 1.

TABLE 1

| characteristic | value | |
|---|---|---|
| threshold voltage (V_{TH}) | −2.5 | V |
| electric field effect mobility (μ_{FE}) | 12.28 | cm²/Vs |
| saturation mobility (saturation mobility) (μₛₐₜ) | 39.69 | cm²/Vs |
| subthreshold swing (SS) | 0.16 | V/dec |
| Hysteresis (Hyst.) | 0 | V |

Referring to FIG. 27A to FIG. 27D along with Table 1, according to the thin film transistor and the manufacturing method thereof according to an embodiment, it may be confirmed that the thin film transistor is capable of acting as a switching element, and characteristics thereof are excellent.

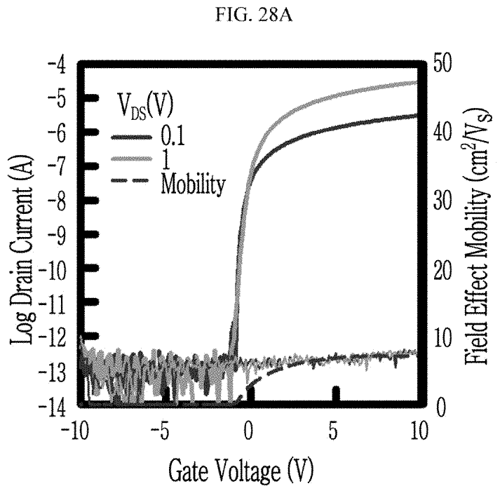

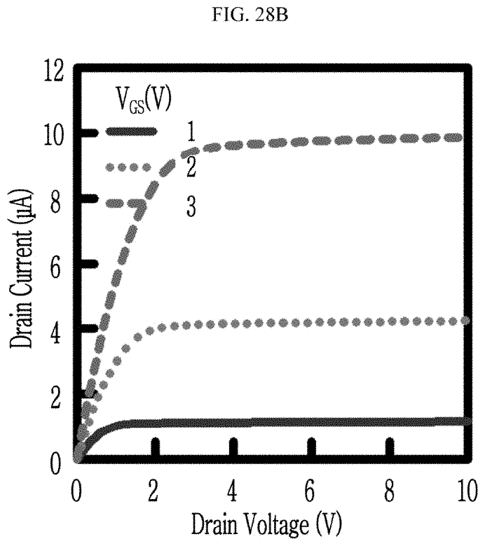

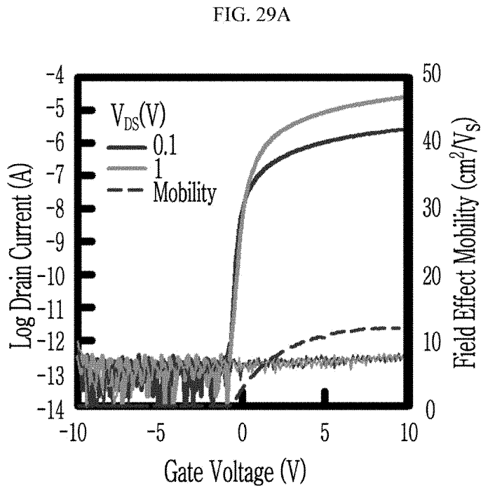

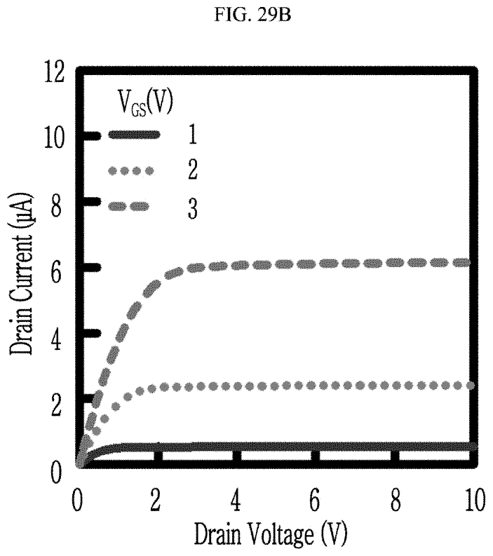

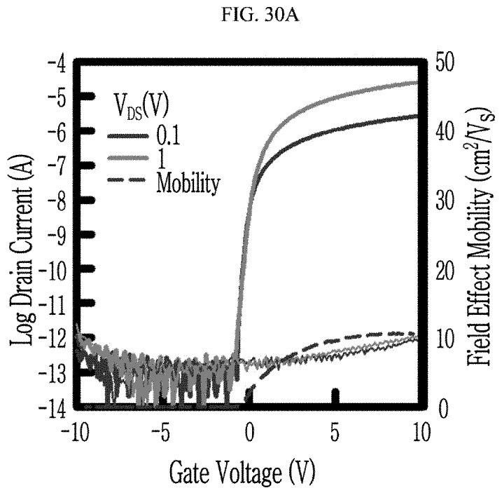

Next, another experimental example is described with reference to FIG. 28A and FIG. 28B, FIG. 29A and FIG. 29B, and FIG. 30A and FIG. 30B. FIG. 28A and FIG. 28B, FIG. 29A and FIG. 29B, and FIG. 30A and FIG. 30B are graphs showing a result of another experimental example.

In this experimental example, like the embodiment described with reference to FIG. 4A and FIG. 4B along with FIG. 2, by stacking the oxide semiconductor layer by the spray coating under the temperature of about 300° C. or higher to form the thin film transistor including the crystallized oxide semiconductor layer of the crystallized IGZO layer, a transfer curve and an output curve of the formed thin film transistor are shown in FIG. 28A and FIG. 28B, FIG. 29A and FIG. 29B, and FIG. 30A and FIG. 30B.

FIG. 28A and FIG. 28B show the result of the thin film transistor including the semiconductor layer formed by stacking the crystallized IGZO layer with a thickness of about 8 nm by the spray coating method, FIG. 29A and FIG. 29B show the result of the thin film transistor including the semiconductor layer formed by stacking the crystallized IGZO layer with a thickness of about 10 nm by the spray coating method, and FIG. 30A and FIG. 30B show the result of the thin film transistor including the semiconductor layer formed by stacking the crystallized IGZO layer with a thickness of about 15 nm by the spray coating method.

In addition, main characteristic values of the thin film transistor formed in this experimental example were measured and are shown in Table 2.

TABLE 2

| semiconductor layer | | | |
|---|---|---|---|
| thickness | characteristic | value | |
| 8 nm | threshold voltage (V_{TH}) | −0.4 | V |
| | electric field effect mobility (μ_{FE}) | 10.63 | cm²/Vs |
| | subthreshold swing (SS) | 0.13 | V/dec |
| 10 nm | threshold voltage (V_{TH}) | −0.5 | V |
| | electric field effect mobility (μ_{FE}) | 11.91 | cm²/Vs |
| | subthreshold swing (SS) | 0.09 | V/dec |
| 15 nm | threshold voltage (V_{TH}) | −0.8 | V |
| | electric field effect mobility (μ_{FE}) | 7.17 | cm²/Vs |
| | subthreshold swing (SS) | 0.04 | V/dec |

Referring to FIG. 28A and FIG. 28B, FIG. 29A and FIG. 29B, and FIG. 30A and FIG. 30B along with Table 2, according to the thin film transistor and the manufacturing method thereof according to the embodiment, it may be seen that the thin film transistor is capable of acting as a switching element, and the characteristics thereof are excellent.

While this invention has been described in connection with what is presently considered to be practical embodiments, it is to be understood that the invention is not limited to the disclosed embodiments. On the contrary, it is intended to cover various modifications and equivalent arrangements included within the spirit and scope of the appended claims.

### DESCRIPTION OF SYMBOLS

110: substrate
120: buffer layer
130: semiconductor layer
141: gate insulating layer
151: gate electrode
160: protection layer
161, 162: contact hole
171: source electrode
172: drain electrode

What is claimed is:

1. A thin film transistor comprising:
a gate electrode positioned on a substrate;
a semiconductor layer overlapping the gate electrode via a gate insulating layer interposed therebetween; and
a source electrode and a drain electrode in contact with the semiconductor layer,
wherein the semiconductor layer includes a crystallized oxide semiconductor, and
the crystallized oxide semiconductor includes a crystal of which an X-ray diffraction (XRD) main peak Miller index (hkI) value is 009.

2. The thin film transistor of claim 1, wherein
the crystal of the crystallized oxide semiconductor includes CAAC (C Axis Aligned Crystal).

3. The thin film transistor of claim 2, wherein
the axes of the CAAC are arranged in line along the thickness direction of the semiconductor layer.

4. The thin film transistor of claim 1, wherein
the semiconductor layer includes indium.

5. The thin film transistor of claim 4, wherein
the semiconductor layer includes at least one among IGZO (Indium-Gallium-Zinc-Oxide), IZTO (Indium-Zinc-Tin-Oxide), IGZTO (Indium-Gallium-Zinc-Tin-Oxide), and IGO (Indium-Gallium-Oxide).

6. The thin film transistor of claim 1, wherein
at least portion of the semiconductor layer is treated by fluorine plasma.

7. A thin film transistor comprising:
a gate electrode positioned on a substrate;
a semiconductor layer overlapping the gate electrode via a gate insulating layer interposed therebetween; and
a source electrode and a drain electrode in contact with the semiconductor layer,
wherein the semiconductor layer includes a crystallized oxide semiconductor,
the crystallized oxide semiconductor includes a CAAC (C Axis Aligned Crystal), and
the axes of the CAAC are arranged in line along the thickness direction of the semiconductor layer.

8. The thin film transistor of claim 7, wherein
the semiconductor layer includes indium.

9. The thin film transistor of claim 8, wherein
the semiconductor layer includes at least one among IGZO (Indium-Gallium-Zinc-Oxide), IZTO (Indium-Zinc-Tin-Oxide), IGZTO (Indium-Gallium-Zinc-Tin-Oxide), and IGO (Indium-Gallium-Oxide).

10. The thin film transistor of claim 7, wherein
at least portion of the semiconductor layer is treated by fluorine plasma.

11. A manufacturing method of a thin film transistor comprising:
forming a gate electrode on a substrate;
forming an semiconductor layer overlapping the gate electrode via a gate insulating layer interposed therebetween on the substrate; and
forming a source electrode and a drain electrode in contact with the semiconductor layer,
wherein the forming of the semiconductor layer includes spray-coating a solution including a volatile solvent, a metal precursor, and a stabilizer on the substrate.

12. The manufacturing method of claim 11, wherein
the spray coating includes:
preparing the solution by mixing the metal precursor and the stabilizer in the volatile solvent;
spraying the solution with a carrier gas on the substrate; and
evaporating the volatile solvent of the solution.

13. The manufacturing method of claim 12, wherein
the spray coating is performed under a temperature of about 300° C. or higher.

14. The manufacturing method of claim 12, wherein
the stabilizer includes ammonium acetate (AA).

15. The manufacturing method of claim 11, wherein
the forming of the semiconductor layer repeats the spray coating several times.

16. The manufacturing method of claim 11, wherein
the metal precursor includes indium.

17. The manufacturing method of claim 16, wherein
the semiconductor layer includes at least one among IGZO (Indium-Gallium-Zinc-Oxide), IZTO (Indium-Zinc-Tin-Oxide), IGZTO (Indium-Gallium-Zinc-Tin-Oxide), and IGO (Indium-Gallium-Oxide).

18. The manufacturing method of claim 11, further comprising
performing a fluorine plasma treatment on at least portion of the semiconductor layer.

19. The manufacturing method of claim 18, wherein
the fluorine plasma treatment is performed on the semiconductor layer by using the gate electrode as a mask to perform the fluorine plasma treatment.
